(19) United States
(12) Patent Application Publication
(10) Pub. No.: US 2025/0169215 A1
(43) Pub. Date: May 22, 2025

(54) IMAGE SENSOR AND METHOD OF FABRICATING THE SAME

(71) Applicant: Samsung Electronics Co., Ltd., Suwon-si (KR)

(72) Inventors: Kook Tae KIM, Suwon-si (KR); Seunghwi YOO, Suwon-si (KR); Jingyun KIM, Suwon-si (KR)

(73) Assignee: Samsung Electronics Co., Ltd., Suwon-si (KR)

(21) Appl. No.: 18/746,308

(22) Filed: Jun. 18, 2024

(30) Foreign Application Priority Data
Nov. 21, 2023 (KR) 10-2023-0162593

(51) Int. Cl. H01L 27/146

(52) U.S. Cl. CPC H10F 39/807; H10F 39/011

(57) ABSTRACT

Disclosed are image sensors and their fabrication methods. The image sensor comprises a semiconductor substrate having a first conductivity type and including a first surface and a second surface opposite to each other, a plurality of photoelectric conversion regions in the semiconductor substrate and having a second conductivity type, and a first pixel isolation structure between the photoelectric conversion regions that are adjacent to each other in a first direction. The first pixel isolation structure includes a first conductive pattern adjacent to the semiconductor substrate and having a shape that extends from the first surface to the second surface, an inner dielectric pattern on an inner lateral surface of the first conductive pattern, a buried dielectric pattern on the inner dielectric pattern, and an etch stop layer between the inner dielectric pattern and the buried dielectric pattern.

### CROSS-REFERENCE TO RELATED APPLICATION

This U.S. nonprovisional application claims priority under 35 U.S.C § 119 to Korean Patent Application No. 10-2023-0162593 filed on Nov. 21, 2023 in the Korean Intellectual Property Office, the disclosure of which is hereby incorporated by reference in its entirety.

### BACKGROUND

Various example embodiments relate to an image sensor and a method of fabricating the same, and more particularly, to an image sensor with improved electrical and/or optical properties, and/or a method of fabricating the same.

An image sensor converts photonic images into electrical signals. Recent advances in computer and communication industries have led to strong demands in high performances image sensors in various consumer electronic devices such as one or more of digital cameras, camcorders, PCSs (personal communication systems), game consoles, security cameras, and medical micro-cameras. An image sensor is classified into a charged coupled device (CCD) and a CMOS image sensor. The CMOS image sensor has a simple operating method, and a size of its product is possibly minimized or reduced because the corresponding signal processing circuit is integrated into a single chip. Alternatively or additionally, the CMOS image sensor uses relatively small power consumption, which is useful in battery-powered application. Alternatively or additionally, since process technology of manufacturing CMOS image sensors is compatible with CMOS process technology, the CMOS image sensors can decrease in fabrication cost. Accordingly, the use of the CMOS image sensor has been rapidly increasing as a result of advances in technology and implementation of high resolution.

### SUMMARY

Some example embodiments of inventive concepts provide an image sensor with improved electrical and optical properties.

Alternatively or additionally, some example embodiments of inventive concepts provide a method of fabricating an image sensor with improved electrical and optical properties.

The objects of present inventive concepts are not limited to the mentioned above, and other objects which have not been mentioned above will be clearly understood to those of ordinary skill in the art from the following description.

According to some example embodiments, an image sensor may comprise: a semiconductor substrate having a first conductivity type and including a first surface and a second surface opposite to each other; a plurality of photoelectric conversion regions in the semiconductor substrate and having a second conductivity type; and a first pixel isolation structure between the photoelectric conversion regions that are adjacent to each other in a first direction. The first pixel isolation structure may include: a first conductive pattern adjacent to the semiconductor substrate and having a shape extending from the first surface to the second surface; an inner dielectric pattern on an inner lateral surface of the first conductive pattern; a buried dielectric pattern on the inner dielectric pattern; and an etch stop layer between the inner dielectric pattern and the buried dielectric pattern.

Alternatively or additionally according to some example embodiments, an image sensor may comprise: a semiconductor substrate having a first conductivity type and including a first surface and a second surface opposite to each other; a plurality of photoelectric conversion regions in the semiconductor substrate and having a second conductivity type; a device isolation layer in the semiconductor substrate and adjacent to the first surface; a first pixel isolation structure between two neighboring ones of the photoelectric conversion regions and including a first etch stop layer; and a second pixel isolation structure between four neighboring ones of the photoelectric conversion regions and including a second etch stop layer. The first etch stop layer and the second etch stop layer may be between a bottom surface of the device isolation layer and the second surface of the semiconductor substrate.

Alternatively or additionally according to some example embodiments, an image sensor may comprise: a semiconductor substrate including a light-receiving area, a light-shielding area, and a pad area and having a first surface and a second surface opposite to each other; a pixel isolation structure in the semiconductor substrate on the light-receiving area and the light-shielding area, the pixel isolation structure defining a plurality of pixel regions and including a first conductive pattern; a transfer gate electrode on the first surface of the semiconductor substrate; a plurality of photoelectric conversion regions in the semiconductor substrate on the light-receiving area and the light-shielding area; a pixel circuit layer on the first surface of the semiconductor substrate; and an optical transmission layer on the second surface of the semiconductor substrate. The pixel isolation structure may include: a plurality of first pixel isolation structures between the pixel regions that are adjacent to each other in a first direction or a second direction that intersects the first direction; and a plurality of second pixel isolation structures between the pixel regions that are adjacent to each other in a third direction diagonal to the first and second directions. The first pixel isolation structure may further include an inner dielectric pattern on an inner lateral surface of the first conductive pattern. The second pixel isolation structure may further include a second conductive pattern on the inner lateral surface of the first conductive pattern.

Alternatively or additionally according to some example embodiments, a method of fabricating an image sensor may comprise: providing a substrate having a first surface and a second surface that are opposite to each other; forming a first trench and a second trench by removing a portion of the semiconductor substrate; forming in the first trench a first pixel isolation structure including an etch stop layer; and forming a second pixel isolation structure in the second trench. The step of forming the first pixel isolation structure may include using a first ion implantation process to form the etch stop layer.

### BRIEF DESCRIPTION OF DRAWINGS

FIG. 1 illustrates a schematic block diagram showing an image sensor according to some example embodiments.

FIGS. 2A and 2B illustrate circuit diagrams showing a pixel of an image sensor according to some example embodiments.

FIG. 3 illustrates a plan view showing an image sensor according to some example embodiments.

FIGS. 4A and 4B illustrate cross-sectional views respectively taken along lines A-A′ and B-B′ of FIG. 3, showing an image sensor according to some example embodiments.

FIGS. 5A to 7B illustrate enlarged cross-sectional views showing an image sensor according to some example embodiments.

FIGS. 5A, 6A, and 7A illustrate enlarged views showing section P1 of FIG. 4A.

FIGS. 5B, 6B, and 7B illustrate enlarged views showing section P2 of FIG. 4B.

FIG. 8 illustrates a simplified plan view showing an image sensor including a semiconductor device according to some example embodiments.

FIGS. 9A and 9B illustrate cross-sectional views taken along line C-C′ of FIG. 8, showing an image sensor according to some example embodiments.

FIGS. 10A to 17B illustrate cross-sectional views showing a method of fabricating an image sensor according to some example embodiments.

FIGS. 10A, 11A, 12A, 13A, 14A, 15A, 16A, and 17A illustrate cross-sectional views taken along line A-A′ of FIG. 3.

FIGS. 10B, 11B, 12B, 13B, 14B, 15B, 16B, and 17B illustrate cross-sectional views taken along line B-B′ of FIG. 3.

FIGS. 18A to 21B illustrate cross-sectional views showing a method of fabricating an image sensor according to some example embodiments.

FIGS. 18A, 19A, 20A, and 21A illustrate cross-sectional views taken along line A-A′ of FIG. 3.

FIGS. 18B, 19B, 20B, and 21B illustrate cross-sectional views taken along line B-B′ of FIG. 3.

### DETAILED DESCRIPTION OF VARIOUS EXAMPLE EMBODIMENTS

The following will now describe some example embodiments with reference to the accompanying drawings. Like reference numerals may indicate like components throughout the description.

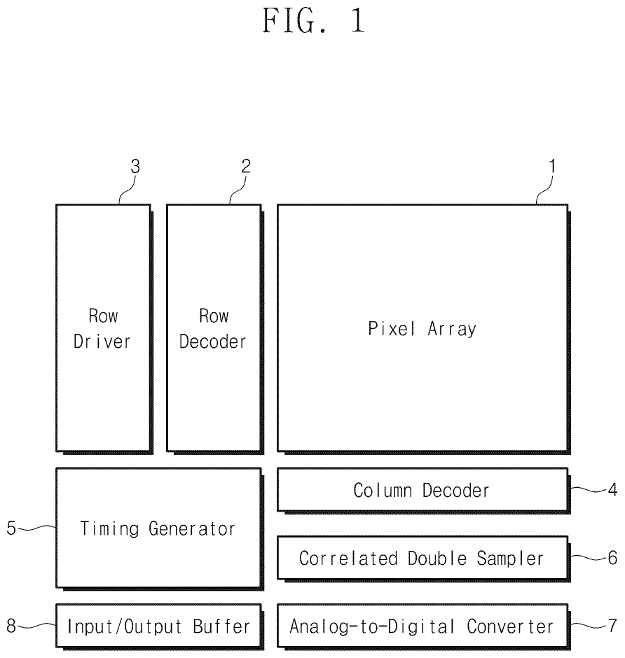

FIG. 1 illustrates a schematic block diagram showing an image sensor according to some example embodiments.

Referring to FIG. 1, an image sensor may include an active pixel sensor array 1, a row decoder 2, a row driver 3, a column decoder 4, a timing generator 5, a correlated double sampler (CDS) 6, an analog-to-digital converter (ADC) 7, and an input/output (I/O) buffer 8. Elements of FIG. 1 may be connected to each other, e.g., wiredly (and/or wirelessly) connected to one another, so as to exchange data and/or information such as analog and/or digital data and/or information such as commands and/or signals, in a serial and/or parallel manner, through a one-to-one channel and/or a many-to-one channel and/or a many-to-many channel.

The active pixel sensor array 1 may include a plurality of two-dimensionally arranged unit pixels, each of which is configured to convert optical signals into electrical signals. The active pixel sensor array 1 may be driven by a plurality of driving signals such as a pixel selection signal, a reset signal, and a charge transfer signal from the row driver 3. The converted electrical signals may be provided for the correlated double sampler 6. The active pixel sensor array 1 may be arranged in a lattice, such as a rectangular (e.g., square) lattice. The active pixel sensor array 1 may include a main array and a redundancy array; example embodiments are not limited thereto.

The row driver 3 may provide the active pixel sensor array 1 with several driving signals for driving several unit pixels in accordance with a decoded result obtained from the row decoder 2. When the unit pixels are arranged in a matrix shape, the driving signals may be provided for each row.

The timing generator 5 may provide the row and column decoders 2 and 4 with timing and control signals.

The correlated double sampler 6 may receive the electrical signals generated in the active pixel sensor array 1, and hold and sample the received electrical signals. The correlated double sampler 6 may perform a double sampling operation to sample a specific noise level and a signal level of the electrical signal, and then output a difference level corresponding to a difference between the noise and signal levels.

The analog-to-digital converter 7 may convert analog signals, which correspond to the difference level received from the correlated double sampler 6, into digital signals, and then may output the converted digital signals.

The input/output buffer 8 may latch the digital signals and then may sequentially output the latched digital signals to an image signal processor (not shown) in response to the decoded result obtained from the column decoder 4.

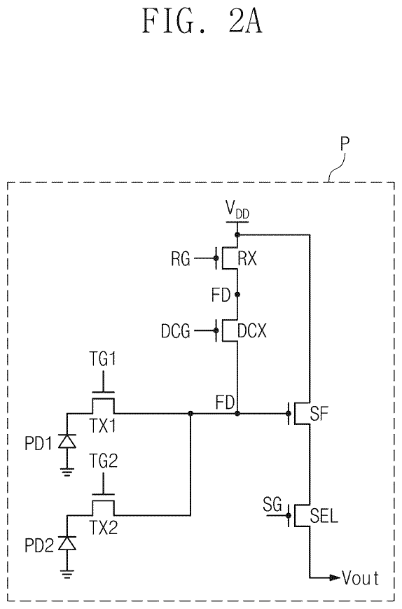

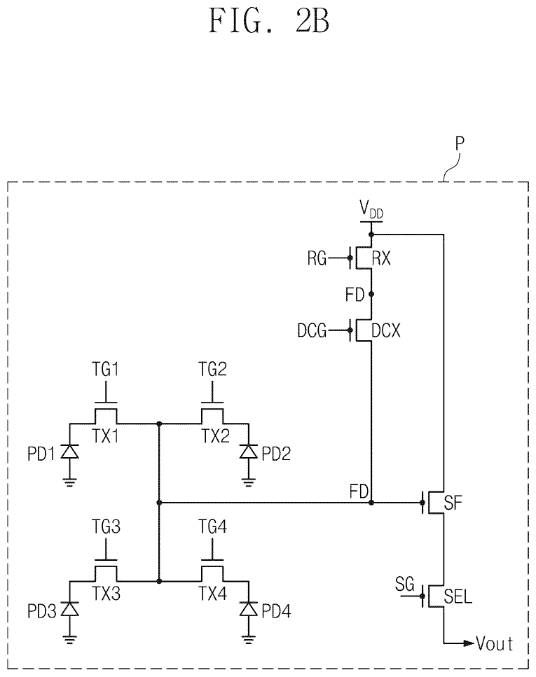

FIGS. 2A and 2B illustrate circuit diagrams showing a pixel of an image sensor according to some example embodiments.

Referring to FIG. 2A, a pixel P may include first and second photoelectric conversion elements PD1 and PD2, first and second transfer transistors TX1 and TX2, and four pixel transistors. For example, the four pixel transistors may include a reset transistor RX, a source follower transistor SF, a selection transistor SEL, and a dual conversion gain transistor DCX, but example embodiments are not limited thereto. For example, on each pixel P, the pixel transistors may be provided in various ways. Each of the pixel transistors may be NMOS transistors and/or PMOS transistors, each having the same and/or different electrical and/or physical characteristics; however, example embodiments are not limited thereto.

The first and second photoelectric conversion elements PD1 and PD2 may generate and accumulate charges in proportion to an amount of incident light. For example, the first and second photoelectric conversion elements PD1 and PD2 may collectively or independently be one of a photo diode, a photo transistor, a photo gate, a pinned photo diode (PPD), and any combination thereof.

The first and second transfer transistors TX1 and TX2 may provide a floating diffusion region FD with the charges accumulated in the first and second photoelectric conversion elements PD1 and PD2. The first and second transfer transistors TX1 and TX2 may be controlled with signals applied to first and second transfer gate electrodes TG1 and TG2. The first and second transfer transistors TX1 and TX2 may share the floating diffusion region FD, but example embodiments are not limited thereto. For example, the first and second transfer transistors TX1 and TX2 may be connected to different floating diffusion regions FD. The first and second transfer transistors TX1 and TX2 may be NMOS transistors having the same electrical and physical characteristics; however, example embodiments are not limited thereto.

The floating diffusion region FD may receive and accumulate charges generated from the first and second photoelectric conversion elements PD1 and PD2. The source follower transistor SF may be controlled in accordance with an amount of photo-charges accumulated in the floating diffusion region FD.

In accordance with a reset signal applied to a reset gate electrode RG, a reset transistor RX may periodically reset the charge accumulated in the floating diffusion region FD. For example, the reset transistor RX may have a drain terminal connected to the dual conversion gain transistor DCX and a source terminal connected to a pixel power voltage V_{DD}. When the reset transistor RX and the dual conversion gain transistor DCX are turned on, the pixel power voltage V_{DD} may be transmitted to the floating diffusion region FD. Thus, the charge accumulated in the floating diffusion region FD may be exhausted to initialize the floating diffusion region FD.

The dual conversion gain transistor DCX may be connected between the floating diffusion region FD and the reset transistor RX. In response to a dual conversion gain control signal, the dual conversion gain transistor DCX may change capacitance of the floating diffusion region FD to control a conversion gain. For example, different conversion gains may be provided in accordance with an operation of the dual conversion gain transistor DCX. Therefore, the dual conversion gain transistor DCX may be turned on in a high illumination mode and turned off in a low illumination mode.

The source follower transistor SF may be or may include (or be included in) a source follower buffer amplifier that generates a source-drain current in proportion to an amount of charges applied to a source follower gate electrode from the floating diffusion region FD. The source follower transistor SF may amplify a variation in electrical potential of the floating diffusion region FD and may output the amplified signal to an output line V_{OUT} through the selection transistor SEL. The source follower transistor SF may be connected to the pixel power voltage V_{DD} and the selection transistor SEL. For example, the source follower transistor SF may be positioned between the pixel power voltage V_{DD} and the selection transistor SEL.

The selection transistor SEL may select each row of the pixels P to be readout. When the selection transistor SEL is turned on in response to a selection signal applied to a selection gate electrode SG, the output line V_{OUT} may output an electrical signal that is output from the drain terminal of the source follower transistor SF.

Referring to FIG. 2B, the pixel P may include first, second, third, and fourth photoelectric conversion elements PD1, PD2, PD3, and PD4, first, second, third, and fourth transfer transistors TX1, TX2, TX3, and TX4, and four pixel transistors.

The first, second, third, and fourth transfer transistors TX1, TX2, TX3, and TX4 may share a floating diffusion region FD. The first, second, third, and fourth transfer transistors TX1, TX2, TX3, and TX4 may be controlled with signals applied to first, second, third, and fourth transfer gate electrodes TG1, TG2, TG3, and TG4. The first, second, third, and fourth transfer transistors TX1, TX2, TX3, and TX4 may have the same, or different, electrical and/or physical characteristics as each other; example embodiments are not limited thereto.

For example, the four pixel transistors may correspond to the reset transistor RX, the source follower transistor SF, the selection transistor SEL, and the dual conversion gain transistor DCX that are discussed in FIG. 2A.

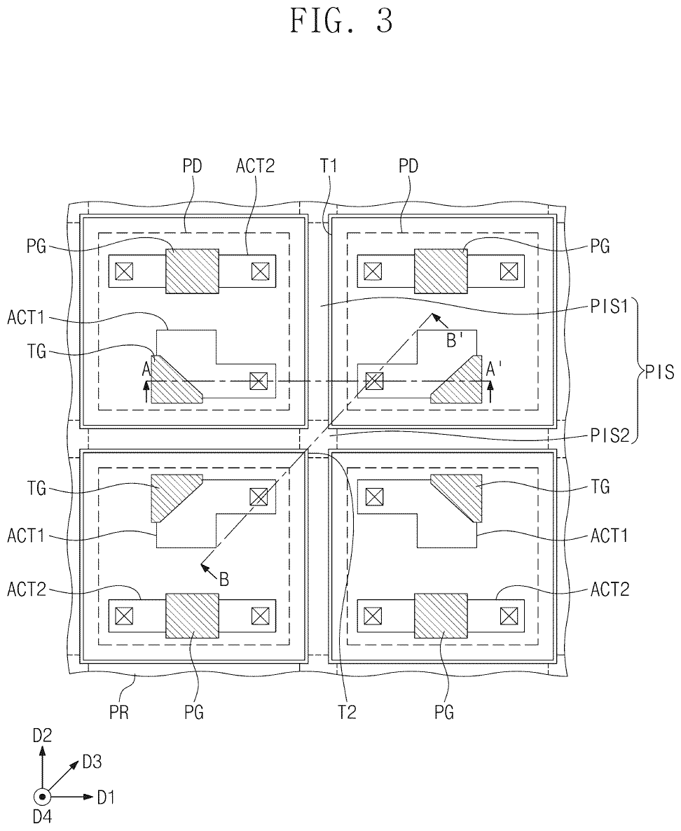

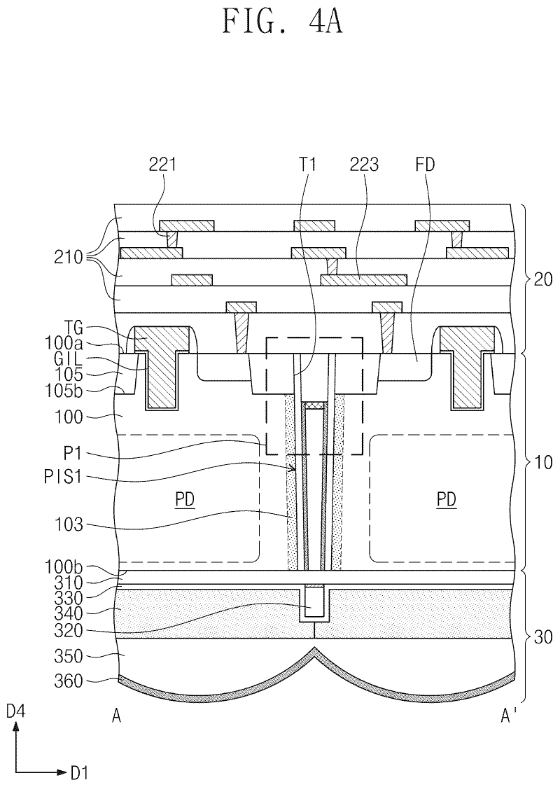

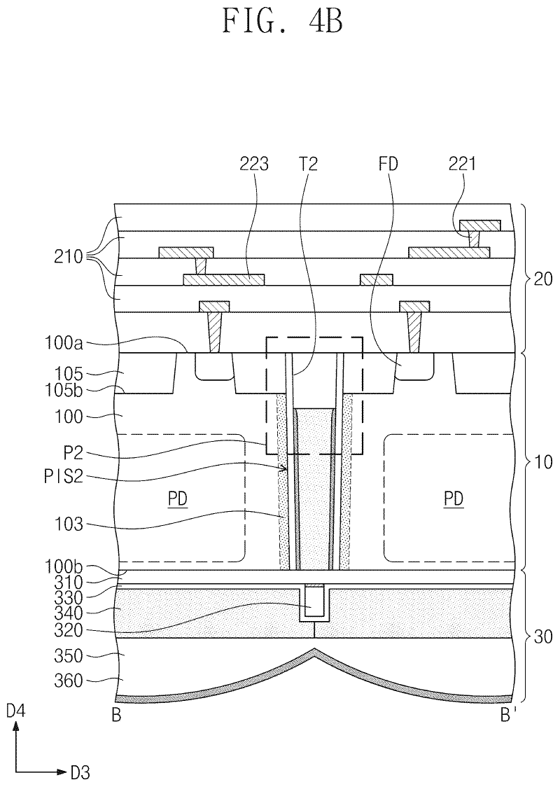

FIG. 3 illustrates a plan view showing an image sensor according to some example embodiments. FIGS. 4A and 4B illustrate cross-sectional views respectively taken along lines A-A′ and B-B′ of FIG. 3, showing an image sensor according to some example embodiments.

Referring to FIGS. 3, 4A, and 4B, an image sensor according to some example embodiments may include a photoelectric conversion layer 10, a pixel circuit layer 20, and an optical transmission layer 30.

When viewed in cross-section, the photoelectric conversion layer 10 may be disposed between the pixel circuit layer 20 and the optical transmission layer 30. The photoelectric conversion layer 10 may convert externally incident light into an electrical signal. The photoelectric conversion layer 10 may include a semiconductor substrate 100, and may also include a pixel isolation structure PIS, a barrier region 103, a device isolation layer 105, and photoelectric conversion regions PD that are positioned within the semiconductor substrate 100.

For example, the semiconductor substrate 100 may have a first surface 100a and a second surface 100b that are opposite to each other. The semiconductor substrate 100 may be or may include a substrate in which an epitaxial layer having a first conductivity type (e.g., p-type) is formed on a bulk silicon substrate having the first conductivity type. Alternatively or additionally, the semiconductor substrate 100 may be or may include a substrate in which an epitaxial layer remains after a bulk silicon substrate is removed in image sensor fabrication. In some example embodiments, the semiconductor substrate 100 may be a bulk silicon substrate including a well having the first conductivity type. For example, the semiconductor substrate 100 may have a substrate having the first conductivity type.

The device isolation layer 105 may be adjacent to the first surface 100a of the semiconductor substrate 100, while being positioned in the semiconductor substrate 100. The device isolation layer 105 may be positioned in a device isolation trench formed by recessing the first surface 100a of the semiconductor substrate 100. A top surface of the device isolation layer 105 may be coplanar with the first surface 100a of the semiconductor substrate 100. The device isolation layer 105 may include a dielectric material. The device isolation layer 105 may define an active section on the first surface 100a of the semiconductor substrate 100. For example, the device isolation layer 105 may define first active sections ACT1 and second active sections ACT2. The first active section ACT1 and the second active section ACT2 may be positioned spaced apart from each other, and may have different sizes from each other.

The pixel isolation structure PIS may be positioned in the semiconductor substrate 100 and may define a plurality of pixel regions PR. When viewed in plan, the pixel isolation structure PIS may surround the plurality of pixel regions PR or photoelectric conversion regions PD. For example, the pixel isolation structure PIS may include first pixel isolation structures PIS1 positioned in first trenches T1 and second pixel isolation structures PIS2 positioned in second trenches T2.

Each of the first trenches T1 may be provided between the pixel regions PR or the photoelectric conversion regions PD that are adjacent to each other in a first direction D1 or a second direction D2. Each of the second trenches T2 may be provided between the pixel regions PR or the photoelectric conversion regions PD that are adjacent to each other in a third direction D3. When viewed in plan, the first trenches T1 may be adjacent to lateral surfaces of the pixel regions PR or the photoelectric conversion regions PD. When viewed in plan, the second trenches T2 may be adjacent to vertices of the pixel regions PR or the photoelectric conversion regions PD. For example, each of the first trenches T1 may be positioned between two of neighboring pixel regions PR and/or neighboring photoelectric conversion regions PD. Each of the second trenches T2 may be positioned between four of neighboring pixel regions PR or neighboring photoelectric conversion regions PD.

The pixel isolation structure PIS may penetrate the semiconductor substrate 100 in a direction from the first surface 100a to the second surface 100b of the semiconductor substrate 100. When viewed in cross-section, the pixel isolation structure PIS may have a shape that extends in a fourth direction D4. The pixel isolation structure PIS may have a length in the fourth direction D4. The length of the pixel isolation structure PIS may be substantially the same as a vertical thickness of the semiconductor substrate 100. The pixel isolation structure PIS may penetrate a portion of the device isolation layer 105.

As described herein, the first direction D1, the second direction D2, and the third direction D3 may be parallel to the first surface 100a and the second surface 100b of the semiconductor substrate 100. The first direction D1, the second direction D2, and the third direction D3 may intersect each other. The first direction D1 and the second direction D2 may be orthogonal to each other. The third direction D3 may be diagonal to the first direction D1 or the second direction D2. The fourth direction D4 may intersect the first direction D1, the second direction D2, and the third direction D3. For example, the fourth direction D4 may be perpendicular to the first surface 100a and the second surface 100b of the semiconductor substrate 100.

The pixel isolation structure PIS may have an upper width at the first surface 100a of the semiconductor substrate 100 and a lower width at the second surface 100b of the semiconductor substrate 100. The lower width of the pixel isolation structure PIS may be less than the upper width of the pixel isolation structure PIS. The pixel isolation structure PIS may have a width that decreases in a direction from the first surface 100a to the second surface 100b of the semiconductor substrate 100, but example embodiments are not limited thereto. For example, the pixel isolation structure PIS may have a width that increases or is constant in a direction from the first surface 100a to the second surface 100b of the semiconductor substrate 100.

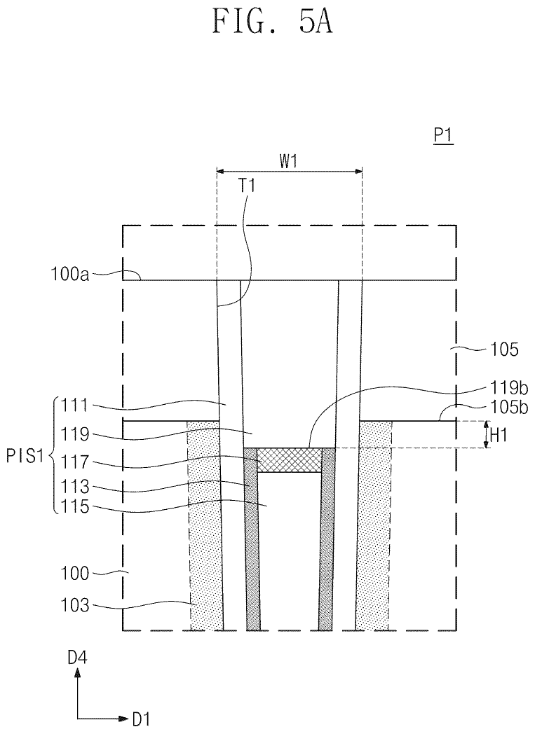

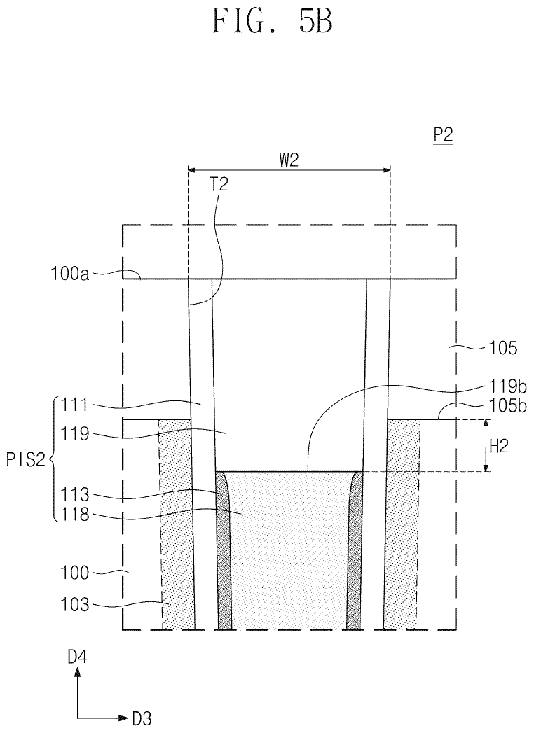

With reference to FIGS. 5A to 7B, the following will describe in detail a structure of each of the first pixel isolation structure PIS1 and the second pixel isolation structure PIS2.

The barrier region 103 may be provided in the semiconductor substrate 100 adjacent to a sidewall of the pixel isolation structure PIS. The barrier region 103 may include impurities having a first conductivity type (e.g., p-type) the same as that of the semiconductor substrate 100. When the first trenches T1 and the second trenches T2 are formed, the barrier region 103 may reduce the occurrence of dark current caused by electron-hole pairs produced due to surface defects of the first trenches T1 and the second trenches T2.

The photoelectric conversion regions PD may be provided in the semiconductor substrate 100 of the pixel regions PR. The photoelectric conversion regions PD may generate photo-charges in proportion to intensity of incident light. The photoelectric conversion regions PD may have a second conductivity type opposite to the first conductivity type of the semiconductor substrate 100. A photodiode may be constituted by junction between the photoelectric conversion region PD having the second conductivity type and the semiconductor substrate 100 having the first conductivity type. The photoelectric conversion regions PD may each have a difference in impurity concentration between a section adjacent to the first surface 100a and a section adjacent to the second surface 100b so as to allow the semiconductor substrate 100 to have a potential gradient between the first surface 100a and the second surface 100b. For example, the photoelectric conversion regions PD may include a plurality of doping regions that are vertically stacked.

The pixel circuit layer 20 may be positioned on the first surface 100a of the semiconductor substrate 100. The pixel circuit layer 20 may include pixel transistors (e.g., MOS transistors) electrically connected to the photoelectric conversion regions PD. For example, the pixel circuit layer 20 may include the reset transistor RX, the selection transistor SEL, the dual conversion gain transistor DCX, and the source follower transistor SF that serve as pixel transistors discussed in FIG. 2A.

On each of the pixel regions PR, a transfer gate electrode TG may be disposed on the first active section ACT1 of the semiconductor substrate 100. The transfer gate electrode TG may be positioned on the first surface 100a of the semiconductor substrate 100. The transfer gate electrode TG may penetrate a portion of the semiconductor substrate 100. When viewed in cross-section, the transfer gate electrode TG may have a T shape. A gate dielectric layer GIL may be provided between the semiconductor substrate 100 and the transfer gate electrode TG.

The floating diffusion region FD may be provided in the first active section ACT1 on one side of the transfer gate electrode TG. The floating diffusion region FD may be formed by implanting the semiconductor substrate 100 with impurities having the second conductivity type opposite to the first conductivity type of semiconductor substrate 100. For example, the floating diffusion region FD may have the second conductivity type.

On each of the pixel regions PR, at least one pixel transistor may be provided on the second active section ACT2. The pixel transistor may be one of the reset transistor RX, the source follower transistor SF, the double conversion gain transistor DCX, and the selection transistor SEL that are discussed with reference to FIGS. 2A and 2B. The pixel transistor may include a pixel gate electrode PG that runs across the second active section ACT2 and source/drain regions provided in the second active section ACT2 on opposite sides of the pixel gate electrode PG. The pixel gate electrode PG may have a bottom surface parallel to a top surface of the second active section ACT2. For example, the pixel gate electrode PG may include doped polysilicon, metal, conductive nitride, conductive metal silicide, conductive metal oxide, or a combination thereof.

A plurality of interlayer dielectric layers 210 may be positioned on the first surface 100a of the semiconductor substrate 100. The interlayer dielectric layers 210 may cover the transfer gate electrode TG and a wiring structure connected to pixel circuits. The wiring structure may include metal lines 223 and contact plugs 221 that connect the metal lines 223 to each other. The number of, and/or the arrangement of, and/or the pitch and/or width and/or spacing of, interlayer dielectric layers 210, metal lines 2223, and contact plugs 221 are not limited to those illustrated in FIG. 4B.

The optical transmission layer 30 may be positioned on the second surface 100b of the semiconductor substrate 100. The optical transmission layer 30 may include a planarized dielectric layer 310, a grid structure 320, a protection layer 330, color filters 340, microlenses 350, and a passivation layer 360. The optical transmission layer 30 may focus and filter externally incident light, and the photoelectric conversion layer 10 may be provided with the focused and filtered light.

For example, the planarized dielectric layer 310 may cover the second surface 100b of the semiconductor substrate 100. The planarized dielectric layer 310 may be formed of a transparent dielectric material and may include a plurality of layers. The planarized dielectric layer 310 may be formed of a dielectric material whose refractive index is different from that of the semiconductor substrate 100. The planarized dielectric layer 310 may include one or more of metal oxide and silicon oxide. For example, the planarized dielectric layer 310 may include one or more of Al₂O₃, CeF₃, HfO₂, ITO, MgO, Ta₂O₂, TiO₂, ZrO₂, Si, Ge, ZnSe, ZnS, or PbF₂. Alternatively or additionally, the planarized dielectric layer 310 may be formed of a high-refractive organic material, such as one or more of siloxane resin, benzocyclobutene (BCB), polyimide, acryl, parylene C, poly(methyl methacrylate) (PMMA), or polyethylene terephthalate (PET). In some example embodiments, the planarized dielectric layer 310 may be formed of one or more of strontium titanate (SrTiO₃), polycarbonate, glass, bromine, sapphire, cubic zirconia, potassium Niobate (KNbO₃), moissanite (SiC), gallium (III) phosphide (GaP), or gallium (III) arsenide (GaAs).

The grid structure 320 may be disposed on the planarized dielectric layer 310. The grid structure 320 may have a planar lattice shape similar to that of the pixel isolation structure PIS. When viewed in plan, the grid structure 320 may overlap the pixel isolation structure PIS. For example, the grid structure 320 may overlap the first pixel isolation structures PIS1 and the second pixel isolation structures PIS2. A width of the grid structure 320 may be substantially the same as or less than a minimum width of the pixel isolation structure PIS.

The grid structure 320 may include one or more of a light-shielding pattern and a low-refractive pattern. The light-shielding pattern may include a metallic material, such as titanium, tantalum, or tungsten. The low-refractive pattern may be formed of a material whose refractive index is less than that of the light-shielding pattern. The low-refractive pattern may be formed of an organic material and may have a refractive index of about 1.1 to about 1.3. For example, the grid structure 320 may be a polymeric layer including silicon nano-particles.

The protection layer 330 may cover surfaces of the planarized dielectric layer 310 and the grid structure 320. The protection layer 330 may have a substantially uniform thickness. For example, the protection layer 330 may be a single or multiple layer including at least one selected from aluminum oxide and silicon carboxide.

The color filters 340 may be formed on the protection layer 330 to correspond to the pixel regions PR. The color filters 340 may fill spaces defined by the grid structure 320. Based on a unit pixel, the color filter 340 may include one of red, green, and blue color filters or one of magenta, cyan, and yellow color filters. The color filters 340 may be arranged in a Bayer pattern; example embodiments are not limited thereto.

The microlenses 350 may be disposed on the color filters 340. The microlenses 350 may each have a convex shape with a certain curvature radius. For example, the microlenses 350 may include a light-transmitting resin.

The passivation layer 360 may be positioned on the microlenses 350 and may have a uniform thickness that covers surfaces of the microlenses 350. For example, the passivation layer 360 may include inorganic oxide.

FIGS. 5A to 7B illustrate enlarged views showing an image sensor according to some example embodiments. FIGS. 5A, 6A, and 7A illustrate enlarged views showing section P1 of FIG. 4A. FIGS. 5B, 6B, and 7B illustrate enlarged views showing section P2 of FIG. 4B.

Referring to FIGS. 5A and 5B, the first pixel isolation structure PIS1 may be positioned in the first trench T1 formed by recessing the first surface 100a of the semiconductor substrate 100. The second pixel isolation structure PIS2 may be positioned in the second trench T2 formed by recessing the first surface 100a of the semiconductor substrate 100. The first trench T1 may have a first width W1 in the first direction D1 at the first surface 100a of the semiconductor substrate 100. The second trench T2 may have a second width W2 in the third direction D3 at the first surface 100a of the semiconductor substrate 100. The first width W1 may be less than the second width W2. Thus, a width in the first direction D1 of the first pixel isolation structure PIS1 may be less than a width in the third direction D3 of the second pixel isolation structure PIS2. The first and second pixel isolation structures P1S1 and P1S2 may have a tapered profile.

The first pixel isolation structure PIS1 and the second pixel isolation structure PIS2 may each independently or collectively include a liner dielectric pattern 111, a first conductive pattern 113, and a buried dielectric pattern 119. The first pixel isolation structure PIS1 may further include an inner dielectric pattern 115 and an etch stop layer 117. The second pixel isolation structure PIS2 may further include a second conductive pattern 118.

The liner dielectric pattern 111 may be positioned on inner sidewalls of the first trench T1 and the second trench T2. The liner dielectric pattern 111 may have a uniform thickness that covers the inner sidewalls of the first trench T1 and the second trench T2. The liner dielectric pattern 111 may be in direct contact with the semiconductor substrate 100. As the liner dielectric pattern 111 includes a material whose refractive index is less than that of the semiconductor substrate 100, the liner dielectric pattern 111 may have a refractive index less than that of the semiconductor substrate 100. The liner dielectric pattern 111 may include one or more of silicon-based dielectric materials (e.g., one or more of silicon nitride, silicon oxide, and silicon oxynitride), high-k dielectric materials (e.g., one or more of hafnium oxide and aluminum oxide), and metal oxides. In addition, the liner dielectric pattern 111 may include impurities having the first conductivity type. For example, the impurities having the first conductivity type may include at least one selected from boron (B), phosphorus (P), arsenic (As), gallium (Ga), indium (In), antimony (Sb), and aluminum (Al).

In the first trench T1 and the second trench T2, the first conductive pattern 113 may be positioned on inner lateral surfaces of the liner dielectric pattern 111. The first conductive pattern 113 may cover portions of the inner lateral surfaces of the liner dielectric pattern 111. The first conductive pattern 113 may not cover remaining portions of the inner lateral surfaces of the liner dielectric pattern 111 adjacent to the first surface 100a of the semiconductor substrate 100. For example, the first conductive pattern 113 may include impurity-doped polysilicon or impurity-undoped polysilicon.

The first conductive pattern 113 in the first trench T1 may have a top surface parallel to the first direction D1. In contrast, the first conductive pattern 113 in the second trench T2 may include an upper portion having a curved surface. For example, the first conductive pattern 113 in the second trench T2 may have a thickness in the third direction D3 that decreases with decreasing distance from a bottom surface 119b of the buried dielectric pattern 119 and the first surface 100a of the semiconductor substrate 100.

In the first trench T1, a first height H1 in the fourth direction D4 may be provided between the top surface of the first conductive pattern 113 and a bottom surface 105b of the device isolation layer 105. In the second trench T2, a second height H2 in the fourth direction D4 may be provided between the top surface of the first conductive pattern 113 and the bottom surface 105b of the device isolation layer 105. The first height H1 may be less than the second height H2, but example embodiments are not limited thereto. For example, the first height H1 may be substantially the same as the second height H2. The first height H1 and the second height H2 may range from about 5 nm to about 1,000 nm.

The inner dielectric pattern 115 may be positioned on inner lateral surfaces of the first conductive pattern 113. The inner dielectric pattern 115 may be positioned at a center in the first direction D1 of the first trench T1. For example, as the inner dielectric pattern 115 is position at a center of the first pixel isolation structure PIS1, the first conductive pattern 113 may be placed between the inner dielectric pattern 115 and the liner dielectric pattern 111. The inner dielectric pattern 115 may not be provided in the second trench T2. As the inner dielectric pattern 115 includes a material whose refractive index is less than that of the first conductive pattern 113, the inner dielectric pattern 115 may have a refractive index less than that of the first conductive pattern 113. For example, the inner dielectric pattern 115 may include a material substantially the same as that of the liner dielectric pattern 111, but example embodiments are not limited thereto.

The etch stop layer 117 may be positioned on the inner dielectric pattern 115. In the first trench T1, the etch stop layer 117 may be positioned between the inner dielectric pattern 115 and the buried dielectric pattern 119 which will be discussed below. In some example embodiments, the etch stop layer 117 may not be provided in the second trench T2. A top surface of the etch stop layer 117 may be coplanar with a top surface of the first conductive pattern 113. For example, the etch stop layer 117 may be positioned between the bottom surface 105b of the device isolation layer 105 and the second surface 100b of the semiconductor substrate 100 depicted in FIG. 4A. For example, the first height H1 in the fourth direction D4 may be provided between the top surface of the etch stop layer 117 and the bottom surface 105b of the device isolation layer 105.

The etch stop layer 117 may include a material having an etch selectivity with respect to an etching process. For example, the etch stop layer 117 may include one or more of an impurity-doped silicon-based dielectric material (e.g., silicon nitride, silicon oxide, and/or silicon oxynitride) and a high-k dielectric material (e.g., hafnium oxide and/or aluminum oxide). Impurities doped into the etch stop layer 117 may include at least one selected from boron (B), carbon (C), silicon (Si), and argon (Ar). For example, the etch stop layer 117 may be formed by doping a portion of the inner dielectric pattern 115 with impurities.

The second conductive pattern 118 may be positioned on the inner lateral surfaces of the first conductive pattern 113. The second conductive pattern 118 may be positioned at a center in the third direction D3 of the second trench T2. For example, as the second conductive pattern 118 is position at a center of the second pixel isolation structure PIS2, the first conductive pattern 113 may be placed between the second conductive pattern 118 and the liner dielectric pattern 111. A top surface of the second conductive pattern 118 may be coplanar with a top surface of the first conductive pattern 113. For example, the second height H2 in the fourth direction D4 may be provided between the top surface of the second conductive pattern 118 and the bottom surface 105b of the device isolation layer 105. The second conductive pattern may include a material substantially the same as that of the first conductive pattern 113, but example embodiments are not limited thereto.

The buried dielectric pattern 119 may be positioned in an upper portion of the first trench T1 and an upper portion of the second trench T2. For example, in the first trench T1, the buried dielectric pattern 119 may be positioned on the etch stop layer 117. In the second trench T2, the buried dielectric pattern 119 may be positioned on the second conductive pattern 118. The buried dielectric pattern 119 may have a top surface and a bottom surface 119b opposite to the top surface. The top surface of the buried dielectric pattern 119 may be coplanar with the first surface 100a of the semiconductor substrate 100. The bottom surface 119b of the buried dielectric pattern 119 may be lower than the bottom surface 105b of the device isolation layer 105. A thickness in the fourth direction D4 of the buried dielectric pattern 119 may be greater than a thickness in the fourth direction D4 of the device isolation layer 105.

For example, because in the first trench T1 the bottom surface 119b of the buried dielectric pattern 119 is in contact with etch stop layer 117, the first height H1 in the fourth direction D4 may be provided between the bottom surface 119b of the buried dielectric pattern 119 and the bottom surface 105b of the device isolation layer 105. Because in the second trench T2 the bottom surface 119b of the buried dielectric pattern 119 is in contact with the second conductive pattern 118, the second height H2 in the fourth direction D4 may be provided between the bottom surface 119b of the buried dielectric pattern 119 and the bottom surface 105b of the device isolation layer 105. For example, the buried dielectric pattern 119 may include a material substantially the same as that of the liner dielectric pattern 111 and/or the inner dielectric pattern 115, but example embodiments are not limited thereto.

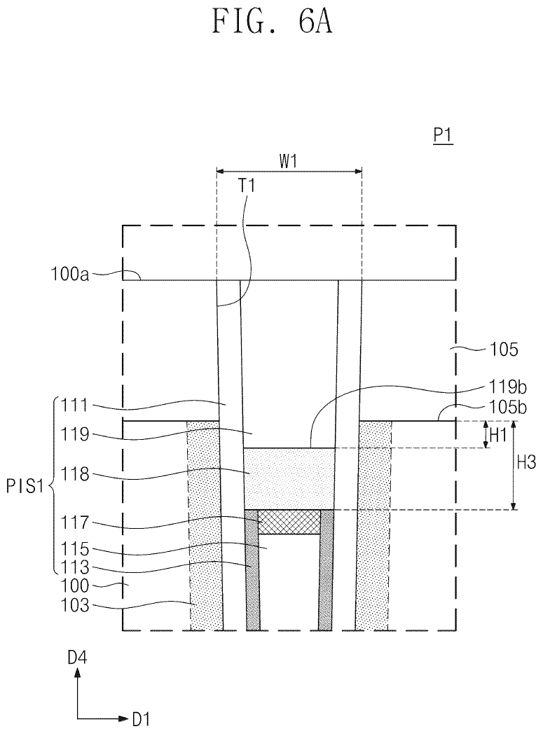

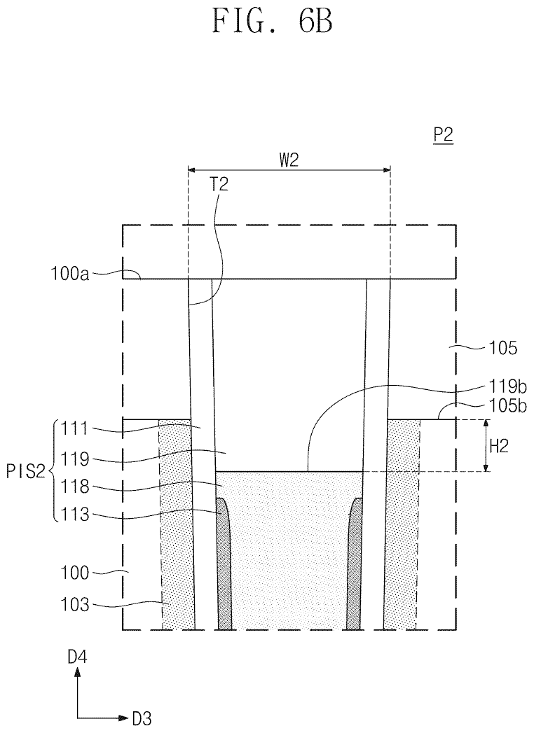

Referring to FIGS. 6A and 6B, the first pixel isolation structure PIS1 may further include a second conductive pattern 118. In the first trench T1, a portion of the second conductive pattern 118 may be positioned between the etch stop layer 117 and the buried dielectric pattern 119. For example, in the first trench T1, a bottom surface of the second conductive pattern 118 may be in contact with the etch stop layer 117 and the first conductive pattern 113, and a top surface of the second conductive pattern 118 may be in contact with the buried dielectric pattern 119. Therefore, in the first trench T1, a third height H3 in the fourth direction D4 may be provided between the top surface of the first conductive pattern 113 and the bottom surface 105b of the device isolation layer 105 and between the top surface of the etch stop layer 117 and the bottom surface 105b of the device isolation layer 105. In the first trench T1, a first height H1 in the fourth direction D4 may be provided between the second conductive pattern 118 and the bottom surface 105b of the device isolation layer 105. The first height H1 may be substantially the same as that discussed in FIGS. 5A and 5B, and the third height H3 may be greater than the first height H1.

In the second trench T2, the top surface of the first conductive pattern 113 may not be coplanar with the top surface of the second conductive pattern 118. The top surface of the second conductive pattern 118 may be higher than the top surface of the first conductive pattern 113. For example, the second conductive pattern 118 may have a T shape. In the second trench T2, a second height H2 in the fourth direction D4 may be provided between the top surface of the second conductive pattern 118 and the bottom surface 105b of the device isolation layer 105. The second height H2 may be substantially the same as that discussed in FIGS. 5A and 5B.

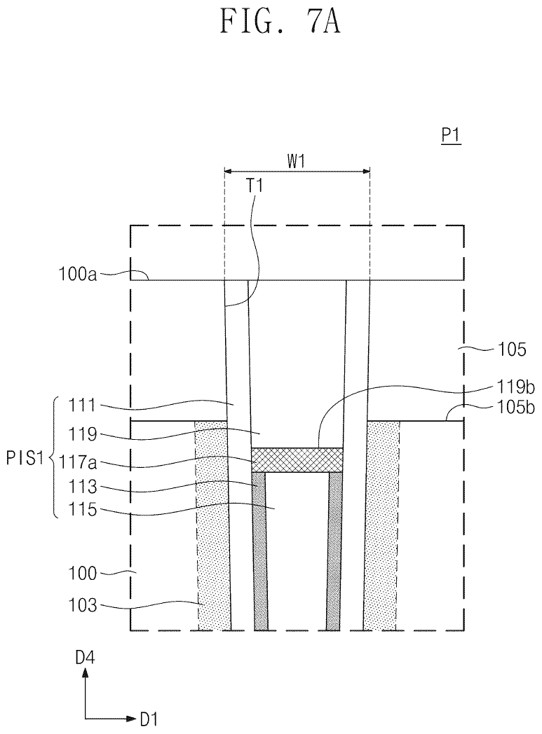

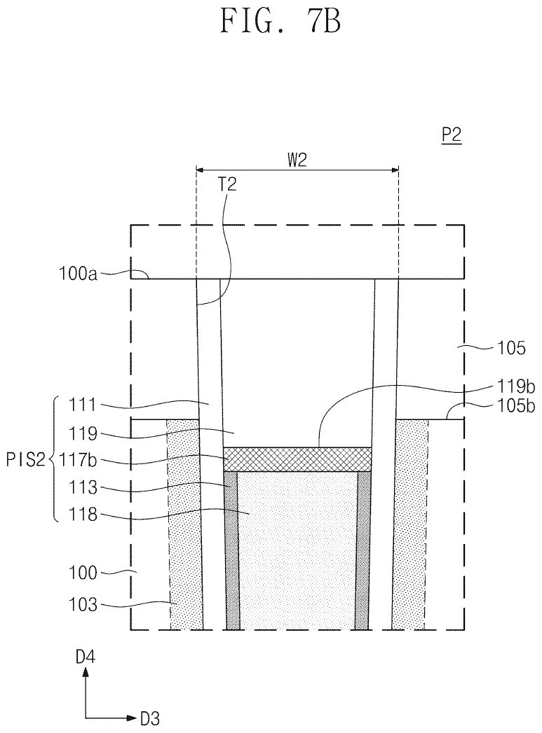

Referring to FIGS. 7A and 7B, the first pixel isolation structure PIS1 may include a first etch stop layer 117a, and the second pixel isolation structure PIS2 may include a second etch stop layer 117b.

In the first trench T1, the first etch stop layer 117a may be positioned between the inner dielectric pattern 115 and the buried dielectric pattern 119 and between the first conductive pattern 113 and the buried dielectric pattern 119. The first etch stop layer 117a may be positioned between the bottom surface 105b of the device isolation layer 105 and the second surface 100b of the semiconductor substrate 100 depicted in FIG. 4A. The top surface of the first conductive pattern 113 may be coplanar with the top surface of the inner dielectric pattern 115.

For example, the first etch stop layer 117a may include one or more of a silicon-based dielectric material (e.g., any one or more of silicon nitride, silicon oxide, and/or silicon oxynitride) including at least one selected from boron (B), carbon (C), silicon (Si), and argon (Ar) and a high-k dielectric material (e.g., hafnium oxide and/or aluminum oxide). According to various example embodiments, the first etch stop layer 117a may be substantially the same as the etch stop layer 117 discussed in FIGS. 5A and 6A.

In the second trench T2, the second etch stop layer 117b may be positioned between the second conductive pattern 118 and the buried dielectric pattern 119 and between the first conductive pattern 113 and the buried dielectric pattern 119. Likewise the first etch stop layer 117a, the second etch stop layer 117b may be positioned between the bottom surface 105b of the device isolation layer 105 and the second surface 100b of the semiconductor substrate 100 depicted in FIG. 4B. The top surface of the first conductive pattern 113 may be coplanar with the top surface of the second conductive pattern 118, and the top surface of the second conductive pattern 118 may be parallel to the third direction D3. Unlike that in FIGS. 5B and 6B, the second conductive pattern 118 may have a thickness that is constant regardless of distance from the bottom surface 119b of the buried dielectric pattern 119 and the first surface 100a of the semiconductor substrate 100. For example, the second etch stop layer 117b may include polysilicon doped with impurities including at least one selected from boron (B), carbon (C), silicon (Si), and argon (Ar).

Referring back to FIGS. 5A to 7B, an image sensor according to some example embodiments may include the first pixel isolation structure PIS1 including the inner dielectric pattern 115. The inner dielectric pattern 115 may be positioned closer than the first conductive pattern 113 to the center of the first pixel isolation structure PIS1, and may have a refractive index less than that of the first conductive pattern 113. Thus, light incident on the image sensor may be or may be more likely to be totally reflected between the first conductive pattern 113 and the inner dielectric pattern 115, and the first pixel isolation structure PIS1 may be prevented or reduced from absorbing the incident light. Accordingly, the image sensor may have an improvement in electrical and/or optical properties.

In addition, the image sensor according to some example embodiments may include the first pixel isolation structure PIS1 including the etch stop layer 117. In fabricating the image sensor, the etch stop layer 117 may determine a level (or height) of the top surface of the first conductive pattern 113. For example, the top surface of the first conductive pattern 113 may be located at substantially the same level as that of the bottom surface 105b of the device isolation layer 105. A vertical length of the first conductive pattern 113 may be substantially the same as that of the semiconductor substrate 100 adjacent to the first pixel isolation structure PIS1 and the second pixel isolation structure PIS2. When viewed in cross-section, the semiconductor substrate 100 may completely overlap the first conductive pattern 113. Thus, a negative bias applied to the first conductive pattern 113 may sufficiently reduce a dark current that occurs between the semiconductor substrate 100 and the first and second pixel isolation structures PIS1 and PIS2. Accordingly, the image sensor may improve in electrical and optical properties.

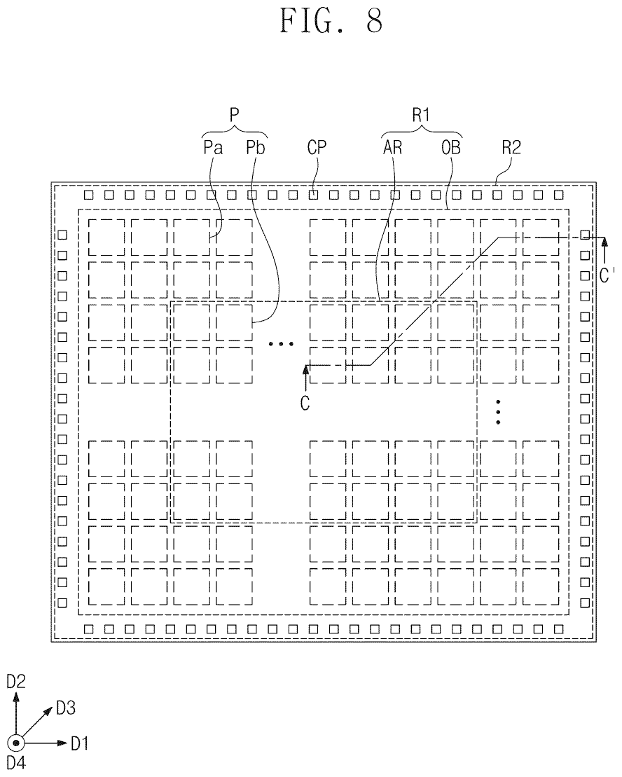

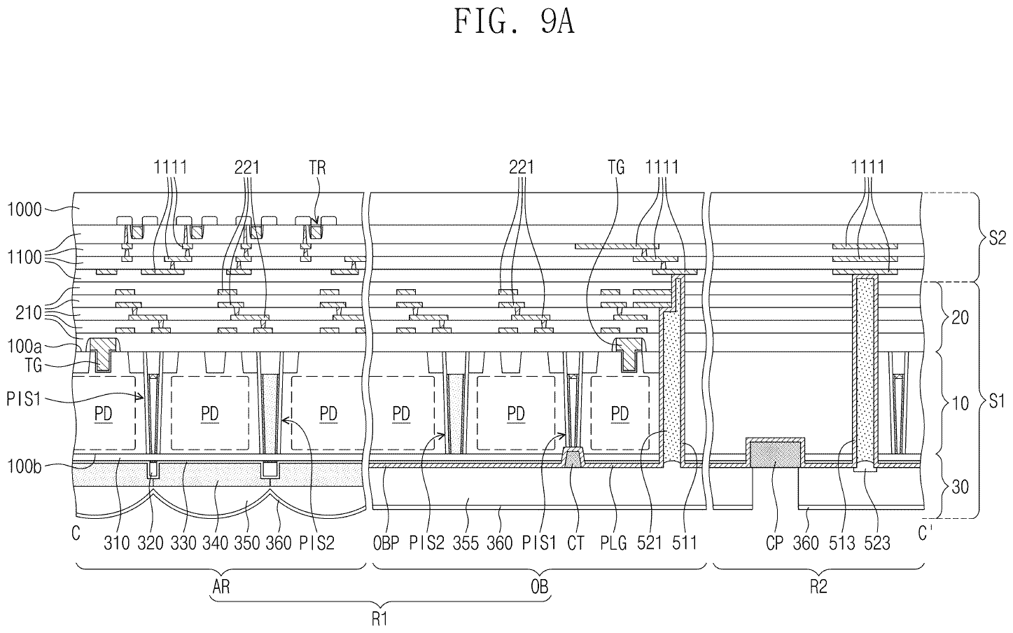

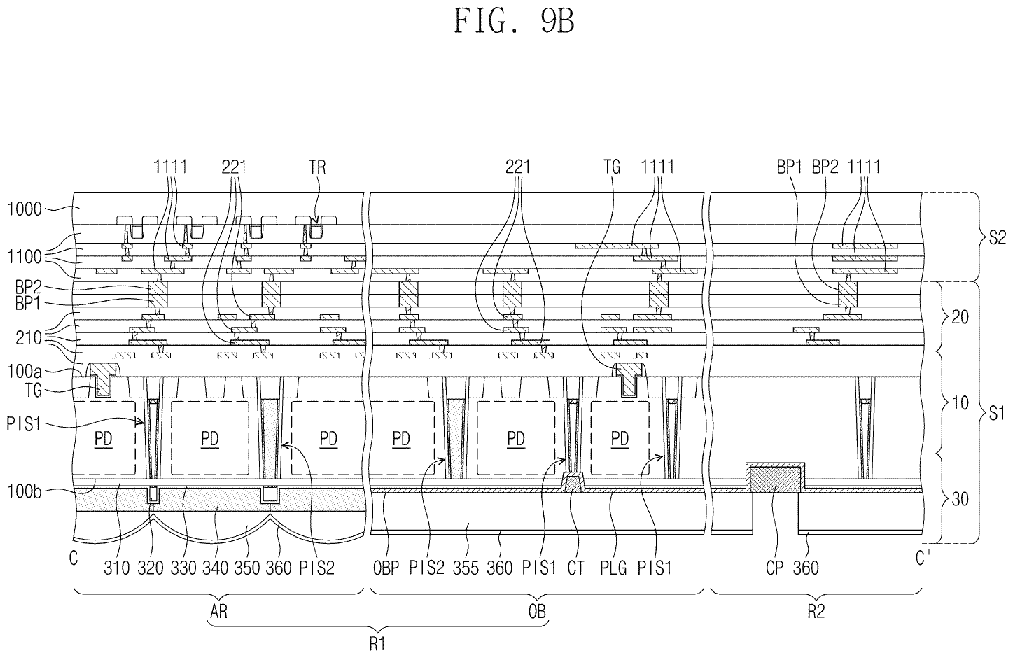

FIG. 8 illustrates a simplified plan view showing an image sensor including a semiconductor device according to some example embodiments. FIGS. 9A and 9B illustrate cross-sectional views taken along line C-C′ of FIG. 8, showing an image sensor according to some example embodiments.

Referring to FIGS. 8 and 9A, an image sensor may include a sensor chip S1 and a logic chip S2. The sensor chip S1 may include a pixel array area R1 and a pad area R2.

The pixel array area R1 may include a plurality of pixels P that are two-dimensionally arranged along a first direction D1 and a second direction D2 that intersect each other. Each of the pixels P may include a photoelectric conversion element and readout elements. Each of the pixels P on the pixel array area R1 may output an electrical signal converted from incident light.

The pixel array area R1 may include a light-receiving area AR and a light-shielding area OB. When viewed in plan, the light-shielding area OB may surround the light-receiving area AR. For example, when viewed in plan, the light-shielding area OB may be disposed to be on an upside, a downside, a left-side, and a right-side of the light-receiving area AR. The light-shielding area OB may include reference pixels Pa on which no light is incident, and an amount of charges sensed in unit pixels Pb on the light-receiving area AR may be compared with a reference amount of charges generated from the reference pixels Pa, which may result in obtaining magnitudes of electrical signals sensed in the unit pixels Pb.

The pad area R2 may include a plurality of conductive pads CP used for input and output of control signals and photoelectric conversion signals. When viewed in plan, the pad area R2 may surround the pixel array area R1. Thus, the pad area R2 may easily be electrically connected to external apparatus. The conductive pads CP may transfer electrical signals between the unit pixels Pb and an external apparatus.

On the light-receiving area AR, the sensor chip S1 may have technical characteristics (such as electrical characteristics and/or physical characteristics) the same as those of the image sensor discussed above. For example, the sensor chip S1 may include a photoelectric conversion layer 10 between a pixel circuit layer 20 and an optical transmission layer 30.

First pixel isolation structures PIS1 may be provided between the pixels P that are adjacent to each other in the first direction D1 or the second direction D2. Second pixel isolation structures PIS2 may be provided between the pixels P that are adjacent to each other in a diagonal direction (e.g., a third direction D3). For example, each of the first pixel isolation structures PIS1 may be positioned between two neighboring pixels P, and each of the second pixel isolation structures PIS2 may be positioned between four neighboring pixels P. The first pixel isolation structures PIS1 may be substantially the same as those discussed in FIGS. 5A, 6A, and 7A, and the second pixel isolation structures PIS2 may be substantially the same as those discussed in FIGS. 5B, 6B, and 7B.

On the light-shielding area OB, the optical transmission layer 30 may include a light-shielding pattern OBP, a backside contact plug PLG, a contact pattern CT, an organic layer 355, and a passivation layer 360.

The contact pattern CT may be buried in a contact hole in which the backside contact plug PLG is formed. The contact pattern CT may include a different material from that of the backside contact plug PLG. For example, the backside contact plug PLG may include one or more of titanium and titanium nitride, and the contact pattern CT may include aluminum (Al).

On the light-shielding area OB, one or more of the first and second pixel isolation structures PIS1 and PIS2 may be electrically connected to the backside contact plug PLG and the contact pattern CT. A negative bias may be applied through the contact pattern CT and the backside contact plug PLG to the first pixel isolation structures PIS1 and the second pixel isolation structures PIS2. The negative bias may be transferred from the light-shielding area OB through the first pixel isolation structures PIS1 and the second pixel isolation structures PIS2 to the light-receiving area AR. Thus, it may be possible to reduce a dark current that occurs between the semiconductor substrate 100 and the first pixel isolation structures PIS1 and between the semiconductor substrate 100 and the second pixel isolation structures PIS2.

On the light-shielding area OB, the light-shielding pattern OBP may continuously extend from the backside contact plug PLG to rest on a top surface of a planarized dielectric layer 310. For example, the light-shielding pattern OBP may include the same material as that of the backside contact plug PLG. The light-shielding pattern OBP may include one or more of metal and metal nitride. For example, the light-shielding pattern OBP may include one or more of titanium and titanium nitride. The light-shielding pattern OBP may not extend to the light-receiving area AR of the pixel array area R1.

The light-shielding pattern OBP may not allow light to travel toward photoelectric conversion regions PD provided on the light-shielding area OB. On the reference pixels Pa of the light-shielding area OB, the photoelectric conversion regions PD may output noise signals without outputting photoelectric signals. The noise signals may be generated from electrons produced due to heat or dark current.

On the light-shielding area OB, the organic layer 355 and the passivation layer 360 may be provided on the light-shielding pattern OBP. The organic layer 355 may include the same material as that of microlenses 350.

On the light-shielding area OB, a first through conductive pattern 511 may penetrate the semiconductor substrate 100 to come into electrical connection with metal lines 223 of the pixel circuit layer 20 and with a wiring structure 1111 of the logic chip S2. The first through conductive pattern 511 may have bottom surfaces located at different levels. A first buried pattern 521 may be provided in the first through conductive pattern 511. The first buried pattern 521 may include a low-refractive material and may have dielectric properties.

On the pad area R2, conductive pads CP may be provided on the second surface 100b of the semiconductor substrate 100. The conductive pads CP may be buried in the second surface 100b of the semiconductor substrate 100. For example, on the pad area R2, the conductive pads CP may be provided in a pad trench formed on the second surface 100b of the semiconductor substrate 100. The conductive pads CP may include metal, such as one or more of aluminum, copper, tungsten, titanium, tantalum, or any alloy such as a homogenous alloy thereof. A plurality of bonding wires may be bonded to the conductive pads CP in a mounting process of the image sensor. The conductive pads CP may be electrically connected through the bonding wires to an external apparatus.

On the pad area R2, a second through conductive pattern 513 may penetrate the semiconductor substrate 100 to come into electrical connection with the wiring structure 1111. The second through conductive pattern 513 may extend onto the second surface 100b of the semiconductor substrate 100 to come into electrical connection with the conductive pads CP. A portion of the second through conductive pattern 513 may cover bottom surfaces and sidewalls of the conductive pads CP. A second buried pattern 523 may be provided in the second through conductive pattern 513. The second buried pattern 523 may include a low-refractive material and may have dielectric properties. On the pad area R2, the second pixel isolation structures PIS2 may be provided around the second through conductive pattern 513.

The logic chip S2 may include a logic semiconductor substrate 1000, logic circuits TR, wiring structures 1111 connected to the logic circuits TR, and logic interlayer dielectric layers 1100. An uppermost one of the logic interlayer dielectric layers 1100 may be bonded to the pixel circuit layer 20 of the sensor chip S1. The logic chip S2 may be electrically connected to the sensor chip S1 through the first through conductive pattern 511 and the second through conductive pattern 513.

Referring to FIGS. 8 and 9B, there may be omitted the first and second through conductive patterns 511 and 513 and the first and second buried patterns 521 and 523 of FIG. 9A. Bonding pads of the sensor chip S1 and the logic chip S2 may be bonded to each other to achieve an electrical connection between the sensor chip S1 and the logic chip S2.

For example, the sensor chip S1 of the image sensor may include first bonding pads BP1 positioned at top of the pixel circuit layer 20. The logic chip S2 may include second bonding pads BP2 positioned on the uppermost one of the logic interlayer dielectric layers 1100. For example, the first bonding pads BP1 and the second bonding pads BP2 may be bonded to each other, while being respectively positioned on a bottom surface and a top surface of the sensor chip S1. The first and second bonding pads BP1 and BP2 may include, for example, at least one selected from tungsten (W), aluminum (Al), copper (Cu), tungsten nitride (WN), tantalum nitride (TaN), and titanium nitride (TiN).

A hybrid bonding manner may be employed to directly and electrically connect the first bonding pads BP1 of the sensor chip S1 to the second bonding pads BP2 of the logic chip S2. The term “hybrid bonding” may denote that two components of the same kind are merged at an interface therebetween. For example, when the first and second bonding pads BP1 and BP2 are formed of copper, a copper-to-copper bonding may be employed to physically and electrically connect the first and second bonding pads BP1 and BP2 to each other.

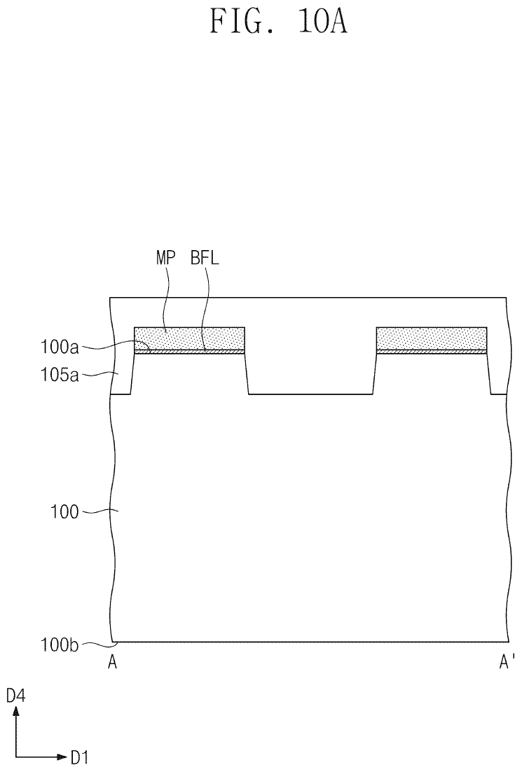

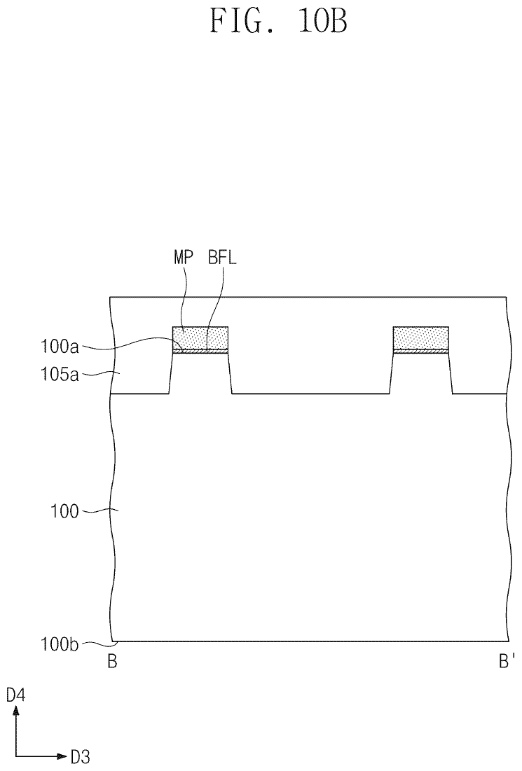

FIGS. 10A to 17B illustrate cross-sectional views showing a method of fabricating an image sensor according to some example embodiments. FIGS. 10A, 11A, 12A, 13A, 14A, 15A, 16A, and 17A illustrate cross-sectional views taken along line A-A′ of FIG. 3. FIGS. 10B, 11B, 12B, 13B, 14B, 15B, 16B, and 17B illustrate cross-sectional views taken along line B-B′ of FIG. 3.

Referring to FIGS. 10A and 10B, a semiconductor substrate 100 may be provided which has a first conductivity type (e.g., p-type), and in some instances may be doped, e.g., lightly doped, e.g., with boron (B). The semiconductor substrate 100 may have a first surface 100a and a second surface 100b that are opposite to each other. The semiconductor substrate 100 may include an epitaxial layer having the first conductivity type formed on a bulk silicon substrate having the first conductivity type. For example, the epitaxial layer may be formed by performing a selective epitaxial growth (SEG) process in which the bulk silicon substrate is used as a seed, and impurities having the first conductivity type may be doped during the selective epitaxial growth process, and/or afterwards, e.g., afterwards with an ion implantation process.

According to some example embodiments, the semiconductor substrate 100 may be or may include a bulk silicon substrate including a well having the first conductivity type, a silicon-on-insulator (SOI) substrate, a germanium substrate, a germanium-on-insulator (GOI) substrate, or a silicon-germanium substrate.

The first surface 100a of the semiconductor substrate 100 may be patterned to form a device isolation trench. The device isolation trench may define first and second active sections ACT1 and ACT2 of FIG. 3. The device isolation trench may be formed by forming a buffer layer BFL and a mask pattern MP on the first surface 100a of the semiconductor substrate 100 and using the mask pattern MP as an etching mask to perform an anisotropic etching process.

The buffer layer BFL may be formed by performing a deposition process or a thermal oxidation process on the first surface 100a of the semiconductor substrate 100. For example, the buffer layer BFL may include a silicon oxide layer, and the mask pattern MP may include a silicon nitride layer or a silicon oxynitride layer.

Afterwards, a device isolation dielectric layer 105a may be formed to fill the device isolation trench. The device isolation dielectric layer 105a may be formed by depositing a thick dielectric material on the semiconductor substrate 100 in which the device isolation trench. The device isolation dielectric layer 105a may cover the mask pattern MP, while filling the device isolation trench.

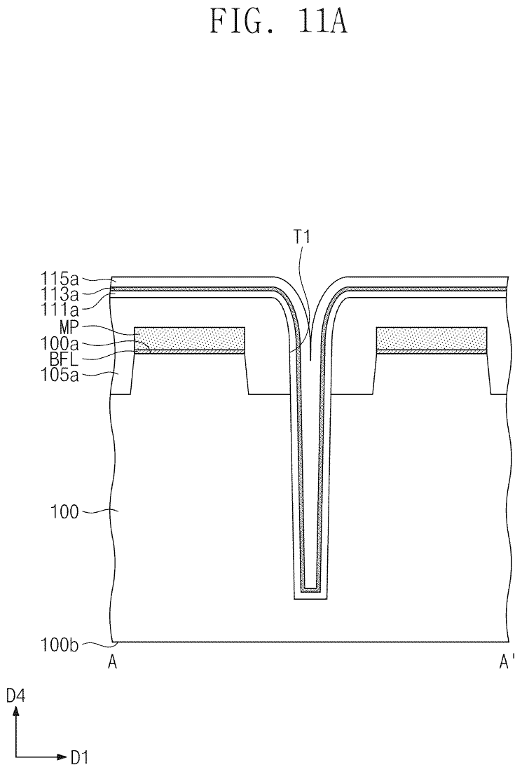

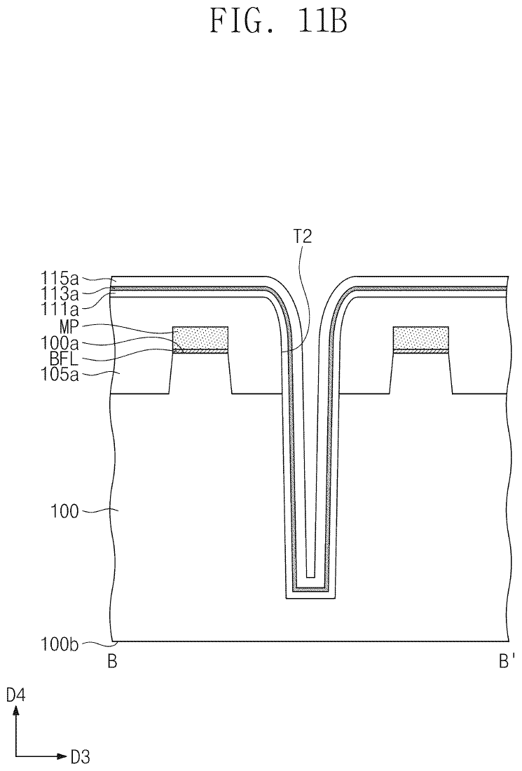

Referring to FIGS. 11A and 11B, a first trench T1 and a second trench T2 may be formed on the semiconductor substrate 100, defining pixel regions PR of FIG. 3. The first trench T1 and the second trench T2 may be formed by patterning the device isolation dielectric layer 105a and the first surface 100a of the semiconductor substrate 100. For example, the first trench T1 and the second trench T2 may be formed by forming a second mask pattern (not shown) on the device isolation dielectric layer 105a, and using the second mask pattern as an etching mask to perform an anisotropic etching process to remove a portion of the semiconductor substrate 100.

The first trench T1 and the second trench T2 may vertically extend from the first surface 100a to the second surface 100b of the semiconductor substrate 100 to partially expose a sidewall of the semiconductor substrate 100. The first trench T1 and the second trench T2 may be formed deeper than the device isolation trench and may penetrate a portion of the device isolation trench. For example, each of the first and second trenches T1 and T2 may be a deep trench having an aspect ratio of about 10:1 to about 15:1, but example embodiments are not limited thereto.

Each of the first and second trenches T1 and T2 may have a width that gradually decreases in a direction from the first surface 100a to the second surface 100b of the semiconductor substrate 100. For example, each of the first and second trenches T1 and T2 may have an inclined sidewall. The first trench T1 and the second trench T2 may have their bottom surfaces spaced apart in a fourth direction D4 from the second surface 100b of the semiconductor substrate 100. Example embodiments, however, are not limited thereto, and each of the first and second trenches T1 and T2 may have a width that is constant along the fourth direction D4.

Each of the first and second trenches T1 and T2 may have a vertical length in the fourth direction D4. The vertical length of the first trench T1 may be substantially the same as that of the second trench T2. The first trench T1 may have a horizontal width in a first direction D1. The second trench T2 may have a horizontal width in a third direction D3. The horizontal width of the first trench T1 may be less than that of the second trench T2. Thus, the same component formed in the first trench T1 and the second trench T2 may have different shapes from each other.

According to some example embodiments, a doping process may be performed on the semiconductor substrate 100. The doping process may include doping impurities having the first conductivity type into the sidewall of the semiconductor substrate 100 exposed by the first trench T1 and the second trench T2. For example, the doping process may include one or more of a beam line ion implantation (BLII) process, a gas phase doping (GPD) process, and a plasma doping (PLAD) process. In a case of the plasma doping process, a process chamber may be supplied with a source material in a gaseous state After the source material is plasma-ionized, a high-voltage bias may be applied to an electrostatic chuck (not shown) on which the semiconductor substrate 100 is loaded, and the ionized source material may be implanted into the sidewall of the semiconductor substrate 100. Therefore, the sidewall of the semiconductor substrate 100 may have an impurity concentration that is uniform regardless of position (or height).

After that, a liner dielectric layer 111a, a first conductive layer 113a, and an inner dielectric layer 115a may be sequentially formed on inner sidewalls of the first trench T1 and the second trench T2. The liner dielectric layer 111a may have a uniform thickness that covers the inner sidewalls of the first trench T1 and the second trench T2. The liner dielectric layer 111a may be deposited by using a deposition process whose step coverage is excellent. For example, the liner dielectric layer 111a may include at least one selected from silicon oxide, silicon nitride, and silicon oxynitride. Alternatively or additionally, the liner dielectric layer 111a may include a multiple layer formed of at least two selected from silicon oxide, silicon nitride, and silicon oxynitride.

The first conductive layer 113a may have a uniform thickness that covers the liner dielectric layer 111a. The first conductive layer 113a may be formed by a deposition method using a precursor. For example, the first conductive layer 113a may include impurity-doped polysilicon. In this case, one or both of diisopropylamino silane (DIPAS) and hexachloro-disilane (HCDS) may be used as a precursor. A thickness of the first conductive layer 113a may be less than that of the liner dielectric layer 111a, but example embodiments are not limited thereto. For example, a doping process may be performed on the first conductive layer 113a. The doping process may include doping impurities having the first conductivity type or a second conductivity type. For example, the doping process may be performed simultaneously with or after the formation of the first conductive layer 113a.

The inner dielectric layer 115a may have a uniform thickness that covers the first conductive layer 113a. Likewise the liner dielectric layer 111a, the inner dielectric layer 115a may be deposited by using a deposition process whose step coverage is excellent. The inner dielectric layer 115a may be formed low within the first trench T1 and the second trench T2. For example, the inner dielectric layer 115a may completely fill a lower portion of the first trench T1. In contrast, the inner dielectric layer 115a may partially fill a lower portion of the second trench T2. As the first trench T1 has a horizontal width less than that of the second trench T2, the inner dielectric layer 115a in the first trench T1 may have a different shape from that of the inner dielectric layer 115a in the second trench T2.

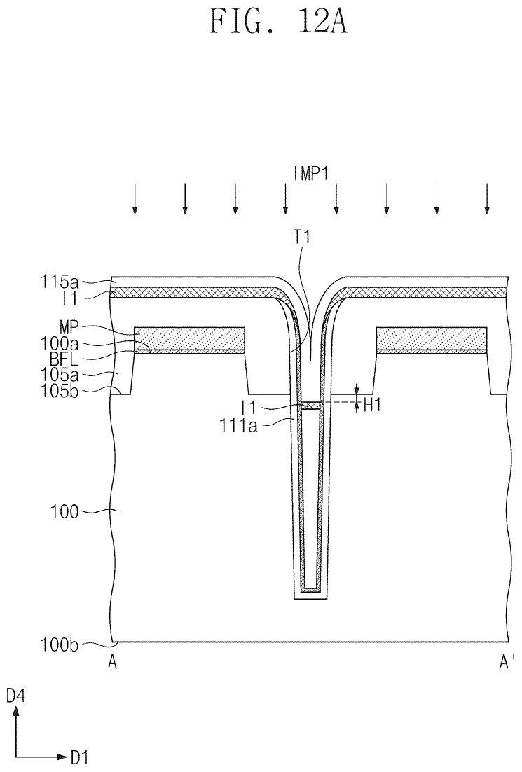

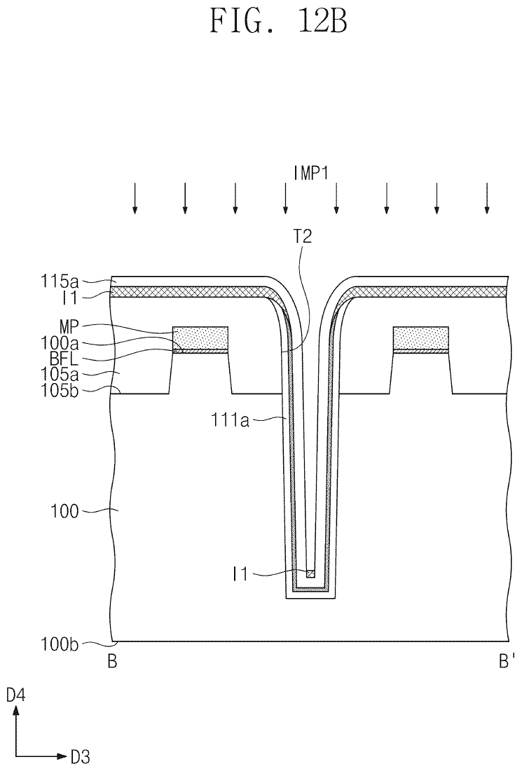

Referring to FIGS. 12A and 12B, a first impurity layer I1 may be formed on the semiconductor substrate 100. The first impurity layer I1 may be formed by a first ion implantation process IMP1 that dopes first impurities. The first impurities may be implanted into the inner dielectric layer 115a to rest between atoms included in the inner dielectric layer 115a. Thus, in an etching process that is subsequently performed to remove the inner dielectric layer 115a, the first impurity layer I1 may be etched at an etch rate relatively less than that of the inner dielectric layer 115a into which no first impurities are doped. In such a case, the first impurity layer I1 may serve as an etch stop layer in the etching process. The first impurities used in the first ion implantation process IMP1 may include, for example, at least one selected from boron (B), carbon (C), silicon (Si), and argon (Ar). For example, the first impurities in the first impurity layer I1 may have a concentration of equal to or greater than about 1×10¹⁴ ions/cm².

According to various example embodiments, the first ion implantation process IMP1 may be performed in a state where the semiconductor substrate 100 is inclined, e.g., inclined relative to the ion beam. In this case, an inclination angle of the semiconductor substrate 100 may range from about 1° to about 4°.

As each of the first trench T1 and the second trench T2 corresponds to a deep trench having a high aspect ratio, the first impurity layer I1 formed by the first ion implantation process IMP1 may be located at different levels in inside and outside the first trench T1 and the second trench T2. For example, in outside the first trench T1 and the second trench T2, the first impurity layer I1 may be formed higher than the first surface 100a of the semiconductor substrate 100. In the first trench T1 and the second trench T2, the first impurity layer I1 may be formed lower than the first surface 100a of the semiconductor substrate 100.

For example, in the first trench T1, the first impurity layer I1 may be formed adjacent to the first surface 100a of the semiconductor substrate 100, and in the second trench T2, the first impurity layer I1 may be formed adjacent to the second surface 100b of the semiconductor substrate 100. The first impurity layer I1 may be formed in the inner dielectric layer 115a. The first impurity layer I1 in the first trench T1 may be formed lower than a bottom surface 105b of the device isolation dielectric layer 105a. A first height H1 in the fourth direction D4 may be provided between a top surface of the first impurity layer I1 in the first trench T1 and the bottom surface 105b of the device isolation dielectric layer 105a. A formation position of the first impurity layer I1 may depend on a doping depth (corresponding to a doping energy) of the first impurities implanted by the first ion implantation process IMP1. For example, the first height H1 may range from about 5 nm to about 1,000 nm.

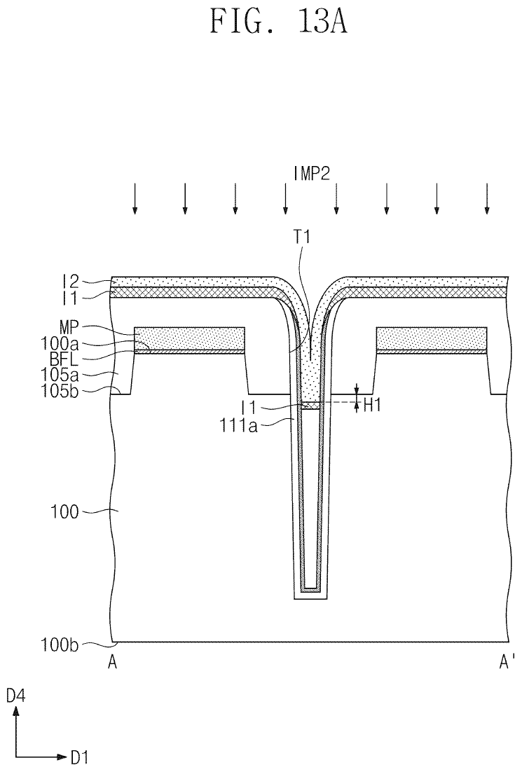

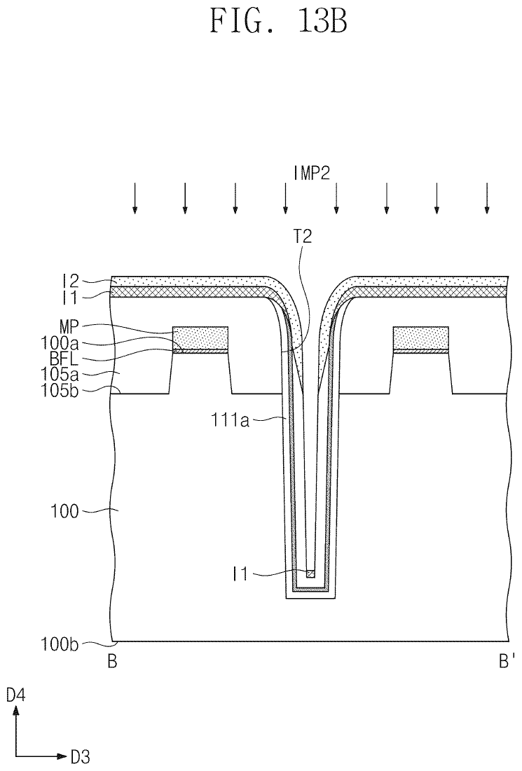

Referring to FIGS. 13A and 13B, a second impurity layer 12 may be formed on the semiconductor substrate 100. The second impurity layer 12 may be formed by a second ion implantation process IMP2 that dopes second impurities. The second impurities may be implanted into the inner dielectric layer 115a to break bonds of atoms included in the inner dielectric layer 115a. Thus, in an etching process that is subsequently performed to remove the inner dielectric layer 115a, the second impurity layer 12 may be etched at an etch rate relatively greater than that of the inner dielectric layer 115a into which no second impurities are doped. In such a case, the second impurity layer 12 may serve as an etch promotion layer in the etching process. There may thus be a large difference in etch rate between the first impurity layer I1 and the second impurity layer 12. The second impurities used in the second ion implantation process IMP2 may include at least one selected from BF3, arsenic (As), and phosphorus (P).

A doping depth of the second impurities implanted by the second ion implantation process IMP2 may be less than the doping depth of the first impurities implanted by the first ion implantation process IMP1. The doping depth corresponding to the first ion implantation process IMP1 and the doping depth corresponding to the second ion implantation process IMP2 may be determined based, for example, on respective energies associated with the respective ion beams. For example, a higher energy may correspond to a deeper implantation profile. Alternatively or additionally, the doping depth may correspond to an atomic mass of respective species used in the implantation. For example, a lower energy ion may correspond to a deeper implantation profile. Thus, the second impurity layer 12 may be positioned on the first impurity layer 11. In this case, the second impurity layer 12 may be formed in upper portions of the first and second trenches T1 and T2. For example, the second impurity layer 12 may be formed higher than the bottom surface 105b of the device isolation dielectric layer 105a. The second impurity layer 12 and the first impurity layer I1 may partially overlap each other. Example embodiments, however, are not limited thereto.

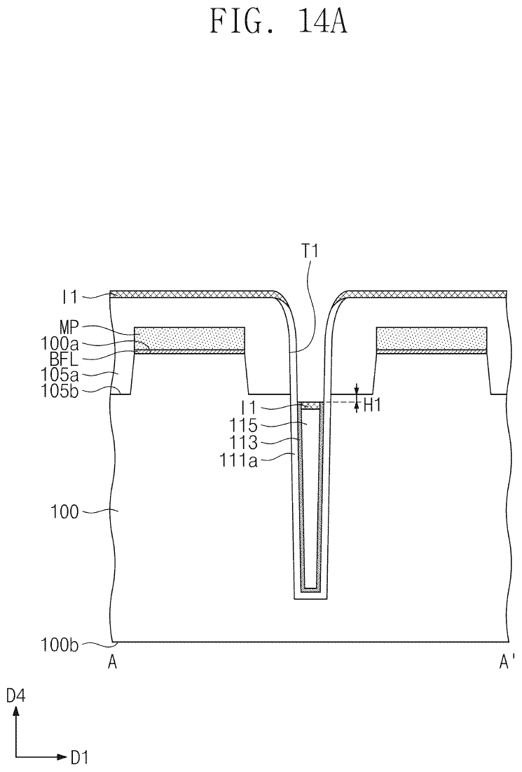

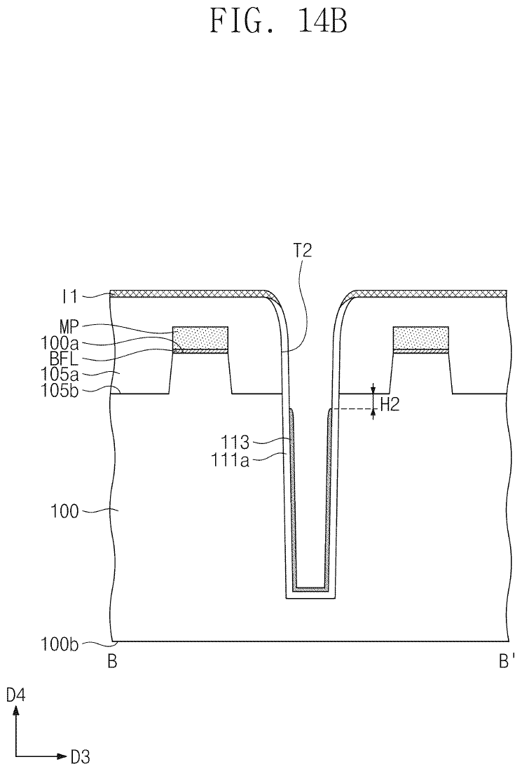

Referring to FIGS. 14A and 14B, an inner dielectric pattern 115 may be formed in the first trench T1. The inner dielectric pattern 115 may be formed by a wet etching process that uses an etch selectivity between the inner dielectric layer 115a, the first impurity layer I1, and the second impurity layer 12. The second impurity layer 12 may have an etch rate greater than that of the inner dielectric layer 115a, and the first impurity layer I1 may have an etch rate less than that of the inner dielectric layer 115a. For example, in the wet etching process, the second impurity layer 12 may serve as an etch promotion layer, and the first impurity layer I1 may serve as an etch stop layer. Hence, in the wet etching process, the second impurity layer 12 may be removed, and the first impurity layer I1 may not be removed.

In the first trench T1, the first impurity layer I1 may close an upper portion of the first trench T1, and thus the inner dielectric layer 115a below the first impurity layer I1 may not be removed. Therefore, a portion of the inner dielectric layer 115a in the first trench T1 may be formed into the inner dielectric pattern 115. In contrast, in the second trench T2, the first impurity layer I1 may not close an upper portion of the first impurity layer I1, and thus the inner dielectric layer 115a may be removed.

For example, the formation of the inner dielectric pattern 115 may include forming the first impurity layer I1 that serves as an etch stop layer, forming the second impurity layer 12 that serves as an etch promotion layer, and removing a portion of the inner dielectric layer 115a including the second impurity layer 12.

Thereafter, a first conductive pattern 113 may be formed in a lower portion of the first trench T1 and a lower portion of the second trench T2. The first conductive pattern 113 may be formed by an etching process that removes a portion of the first conductive layer 113a. For example, an etch-back process may be adopted as the etching process that removes a portion of the first conductive layer 113a.

The etching process may continue until a top surface of the first conductive pattern 113 becomes coplanar with a top surface of the first impurity layer I1 in the first trench T1. A first height H1 in the fourth direction D4 may be provided between the top surface of the first conductive pattern 113 in the first trench T1 and the bottom surface 105b of the device isolation dielectric layer 105a. A second height H2 in the fourth direction D4 may be provided between the top surface of the first conductive pattern 113 in the second trench T2 and the bottom surface 105b of the device isolation dielectric layer 105a. As a horizontal width of the second trench T2 is greater than that of the first trench T1, the first conductive layer 113a in the second trench T2 may be etched more than the first conductive layer 113a in the first trench T1. In this case, the second height H2 may be substantially the same as or greater than the first height H1.

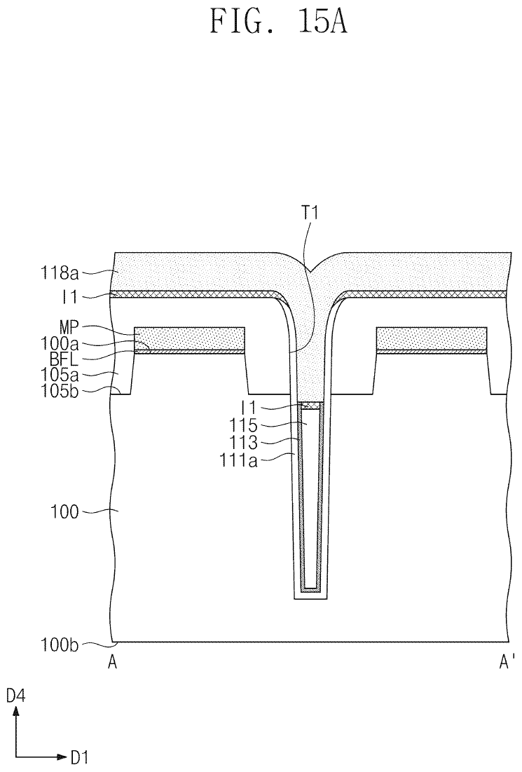

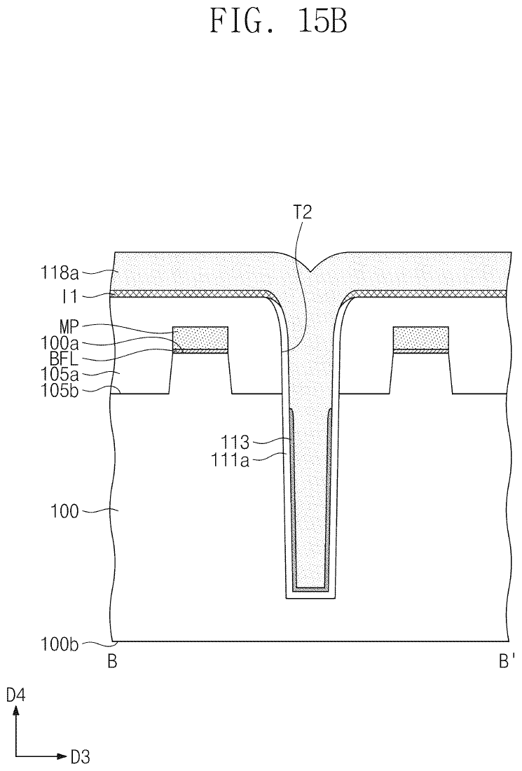

Referring to FIGS. 15A and 15B, a second conductive layer 118a may be formed on the semiconductor substrate 100. In the first trench T1, the second conductive layer 118a may be positioned on the first impurity layer 11. In the second trench T2, the second conductive layer 118a may be positioned on the first conductive pattern 113. For example, the second conductive layer 118a may fill an upper portion of the first trench T1 and upper and lower portions of the second trench T2.

The second conductive layer 118a may be deposited by using a deposition method whose step coverage is excellent, and the deposition method may include low pressure chemical vapor deposition (LPCVD) and/or plasma enhanced chemical vapor deposition (PECVD). The second conductive layer 118a may include impurity-doped polysilicon. For example, the second conductive layer 118a may include substantially the same material as that of the first conductive pattern 113, but example embodiments are not limited thereto.

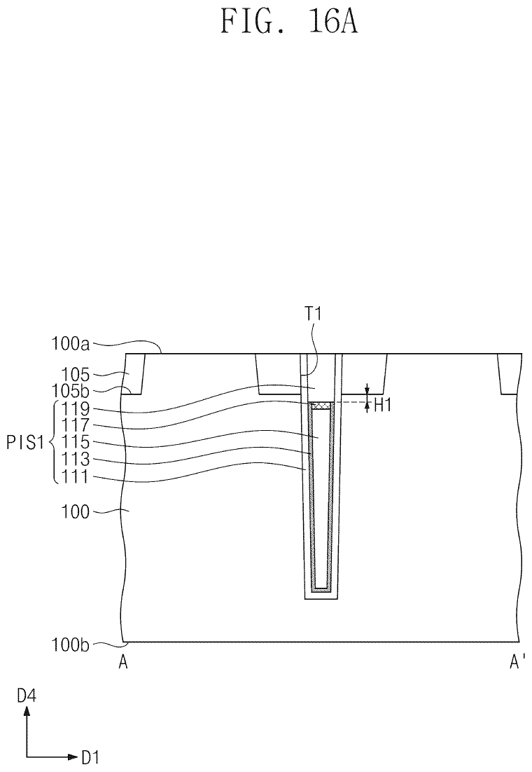

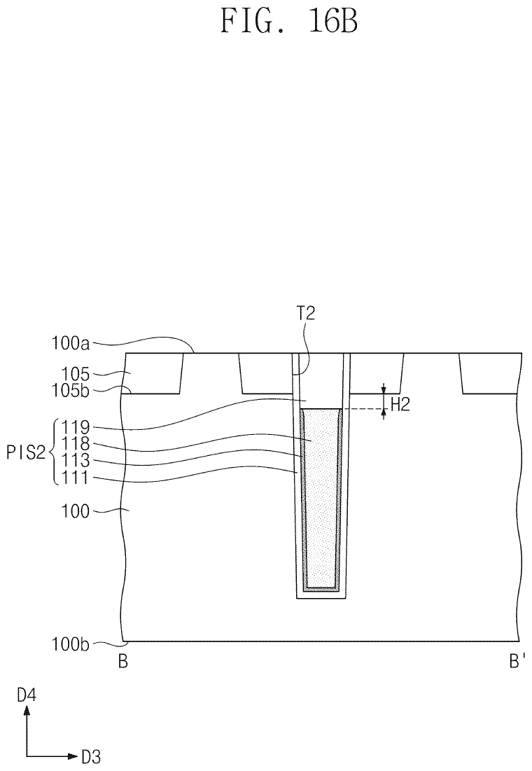

Referring to FIGS. 16A and 16B, a first pixel isolation structure PIS1 may be formed in the first trench T1, and a second pixel isolation structure PIS2 may be formed in the second trench T2. For example, a second conductive pattern 118 may be formed by an etching process that removes a portion of the second conductive layer 118a. The etching process may continue until a top surface of the second conductive pattern 118 becomes coplanar with the top surface of the first conductive pattern 113 in the second trench T2. For example, the formation of the second conductive pattern 118 may be substantially the same as the formation of the first conductive pattern 113. There may thus be removed the second conductive layer 118a formed in the upper portion of the first trench T1 and the upper portion of the second trench T2. Accordingly, the second conductive pattern 118 may be formed only in the second trench T2.

According to some example embodiments, a portion of the second conductive pattern 118 may remain in the first trench T1. As shown in FIGS. 6A and 6B, the second conductive pattern 118 may be formed in the first trench T1 and the second trench T2. In this case, the top surface of the second conductive pattern 118 may be higher than the top surface of the first conductive pattern 113.

Afterwards, a buried dielectric layer (not shown) may be formed to fill the first trench T1 and the second trench T2. The buried dielectric layer may be formed by using a film formation technique whose step coverage is excellent, such as chemical vapor deposition (CVD) and/or atomic layer deposition (ALD). For example, the buried dielectric layer may include one or more of silicon oxide, silicon nitride, and silicon oxynitride.

The mask pattern MP may be removed, and a planarization process may be performed to expose the first surface 100a of the semiconductor substrate 100. The planarization process may remove a portion of the first impurity layer 11, a portion of the device isolation dielectric layer 105a, a portion of the liner dielectric layer 111a, and a portion of the buried dielectric layer. As a result, the device isolation dielectric layer 105a may be formed into a device isolation layer 105, the liner dielectric layer 111a may be formed into a liner dielectric pattern 111, and the buried dielectric layer may be formed into a buried dielectric pattern 119. The first impurity layer I1 in the first trench T1 may be formed into an etch stop layer 117. A top surface of the device isolation layer 105 and a top surface of the buried dielectric pattern 119 may be coplanar with the first surface 100a of the semiconductor substrate 100.

For example, the formation of the first pixel isolation structure PIS1 may include forming the liner dielectric pattern 111, the first conductive pattern 113, the inner dielectric pattern 115, the etch stop layer 117, and the buried dielectric pattern 119 on the inner sidewall of the first trench T1. The formation of the second pixel isolation structure PIS2 may include forming the liner dielectric pattern 111, the first conductive pattern 113, the second conductive pattern 118, and the buried dielectric pattern 119 on the inner sidewall of the second trench T2.

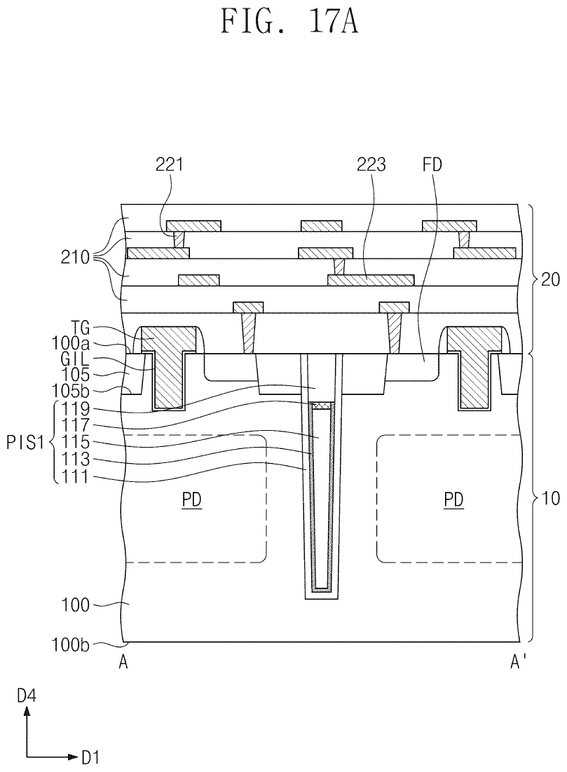

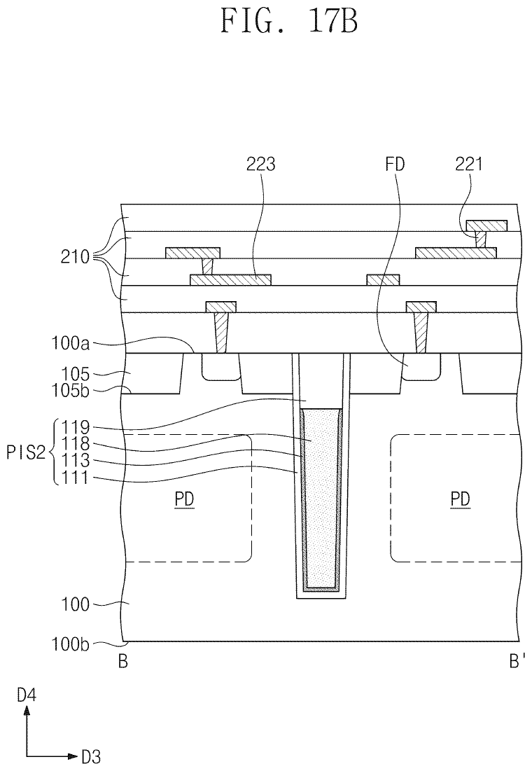

Referring to FIGS. 17A and 17B, photoelectric conversion regions PD having the second conductivity type may be formed in the semiconductor substrate 100. The photoelectric conversion regions PD may be formed by doping the semiconductor substrate 100 with impurities having the second conductivity type (e.g., n-type). The photoelectric conversion regions PD may be spaced apart from the first surface 100a and the second surface 100b of the semiconductor substrate 100. Accordingly, a photoelectric conversion layer 10 of an image sensor may be formed. According to an embodiment, the photoelectric conversion regions PD may be formed before the formation of the first pixel isolation structure PIS1 and the second pixel isolation structure PIS2.

A pixel circuit layer 20 may be formed on the first surface 100a of the semiconductor substrate 100. The formation of the pixel circuit layer 20 may include forming a transfer gate electrode TG, forming floating diffusion regions FD, and forming interlayer dielectric layers 210 and a wiring structure.

The formation of the transfer gate electrode TG may include patterning the semiconductor substrate 100 to form a gate recess region, forming a gate dielectric layer GIL that conformally covers an inner wall of the gate recess region, forming a gate conductive layer that fills the gate recess region, and patterning the gate conductive layer. For example, the formation of the transfer gate electrode TG may include forming a pixel gate electrode PG of FIG. 3.

The formation of the floating diffusion regions FD may include implanting impurities having the second conductivity type into the semiconductor substrate 100 on one side of the transfer gate electrode TG. When the floating diffusion regions FD are formed, source/drain regions of pixel transistors may be simultaneously formed.

The formation of the interlayer dielectric layers 210 and the wiring structure may include forming the interlayer dielectric layers 210 that cover the first surface 100a of the semiconductor substrate 100, and forming in the interlayer dielectric layers 210 the wiring structure connected to the floating diffusion regions FD and pixel transistors. The interlayer dielectric layers 210 may cover MOS transistors that constitute (or correspond to0 pixel circuits. The interlayer dielectric layers 210 may be formed of a material having superior gap-fill characteristics, and may have their planarized upper portions. Contact plugs 221 may be formed in the interlayer dielectric layers 210. A plurality of metal lines 223 may be formed in the interlayer dielectric layers 210. The contact plugs 221 and the metal lines 223 may be formed of, for example, copper (Cu), aluminum (Al), tungsten (W), titanium (Ti), molybdenum (Mo), tantalum (Ta), titanium nitride (TiN), tantalum nitride (TaN), zirconium nitride (ZrN), tungsten nitride (WN), or any alloy thereof.

Referring back to FIGS. 4A and 4B, a thinning process may be performed to remove a portion of the semiconductor substrate 100 to reduce a vertical thickness of the semiconductor substrate 100. The thinning process may include grinding or polishing the second surface 100b of the semiconductor substrate 100 and anisotropically and/or isotropically etching the second surface 100b of the semiconductor substrate 100. The semiconductor substrate 100 may be turned upside down to perform the thinning process thereon.

A planarized dielectric layer 310, a grid structure 320, a protection layer 330, color filters 340, microlenses 350, and a passivation layer 360 may be sequentially formed on the second surface 100b of the semiconductor substrate 100. Accordingly, an optical transmission layer 30 of an image sensor may be formed.

The planarized dielectric layer 310 may cover the second surface 100b of the semiconductor substrate 100. For example, the planarized dielectric layer 310 may be formed by depositing metal oxide, such as one or more of aluminum oxide and hafnium oxide.

The grid structure 320 may include one or more of a light-shielding pattern and a low-refractive pattern. For example, the light-shielding pattern may include a metallic material, such as titanium, tantalum, or tungsten. The low-refractive pattern may be formed of a material whose refractive index is less than that of the light-shielding pattern. The low-refractive pattern may be formed of an organic material and may have a refractive index of about 1.1 to about 1.3. For example, the grid structure 320 may be a polymeric layer including silicon nano-particles.

The planarized dielectric layer 310 may be provided thereon with the protection layer 330 having a substantially uniform thickness that covers a surface of the grid structure 320. For example, the protection layer 330 may include a single or multiple layer of at least one selected from an aluminum oxide layer and a silicon carboxide layer.

The color filters 340 may be formed on the protection layer 330 to correspond to the pixel regions PR. For example, the color filters 340 may include blue, red, and green color filters.

The microlenses 350 may be correspondingly formed on the color filters 340. The microlenses 350 may each have a convex shape with a certain curvature radius. The microlenses 350 may be formed of a light-transmitting resin.

The passivation layer 360 may conformally cover top surfaces of the microlenses 350. For example, the passivation layer 360 may include inorganic oxide.

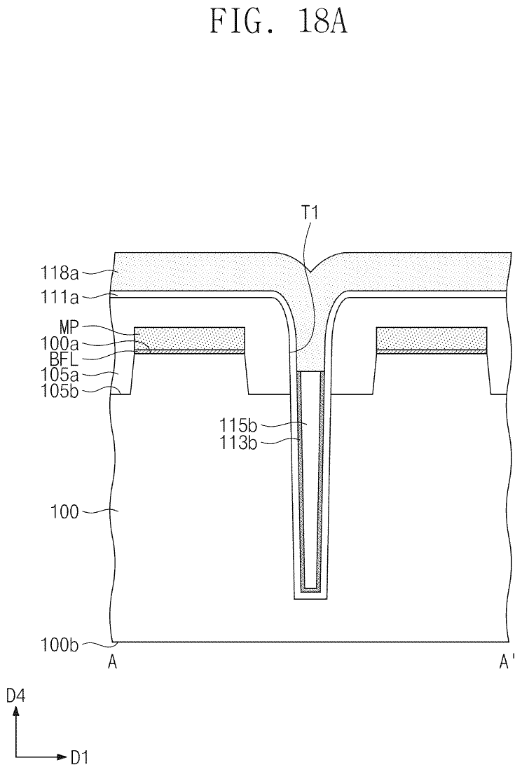

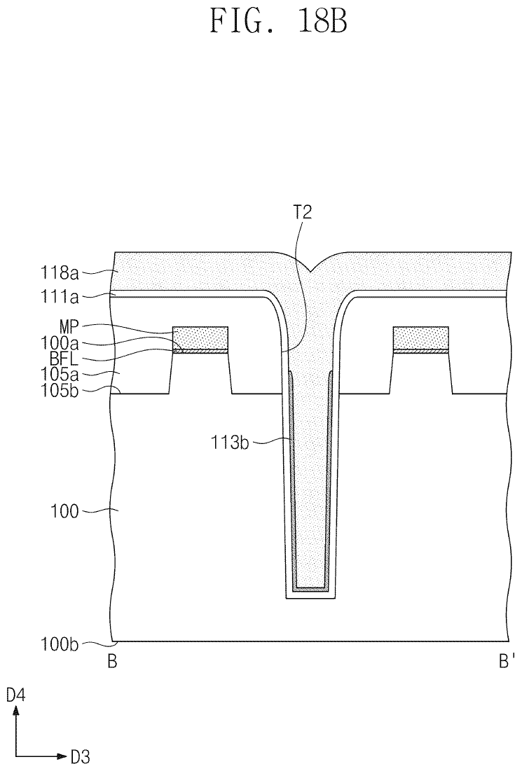

FIGS. 18A to 21B illustrate cross-sectional views showing a method of fabricating an image sensor according to some example embodiments. FIGS. 18A, 19A, 20A, and 21A illustrate cross-sectional views taken along line A-A′ of FIG. 3. FIGS. 18B, 19B, 20B, and 21B illustrate cross-sectional views taken along line B-B′ of FIG. 3.

Referring to FIGS. 18A and 18B, a buffer layer BFL, a mask pattern MP, and a device isolation dielectric layer 105a may be formed on the semiconductor substrate 100. The formation of the buffer layer BFL, the mask pattern MP, and the device isolation dielectric layer 105a may be substantially the same as that discussed in FIGS. 10A and 10B.

A first trench T1 and a second trench T2 may be formed in the semiconductor substrate 100. Substantially the same as that discussed in FIGS. 11A and 11B, a liner dielectric layer 111a, a first conductive layer 113a, and an inner dielectric layer 115a may be formed on inner sidewalls of the first trench T1 and the second trench T2.

A preliminary inner dielectric pattern 115b may be formed in the first trench T1. The preliminary inner dielectric pattern 115b may be formed by a wet etching process that removes a portion of the inner dielectric layer 115a. A horizontal width of the second trench T2 may be greater than that of the first trench T1, and thus the inner dielectric layer 115a may have a relatively large surface area exposed to an etching solution. Therefore, the inner dielectric layer 115a in the second trench T2 may be removed, but the inner dielectric layer 115a in the first trench T1 may only be partially removed. The preliminary inner dielectric pattern 115b may be formed to have a top surface higher than a bottom surface 105b of the device isolation dielectric layer 105a.

A preliminary first conductive pattern 113b may be formed in the first trench T1 and the second trench T2. The preliminary first conductive pattern 113b may be formed by an etching process that removes a portion of the first conductive layer 113a. The etching process that removes a portion of the first conductive layer 113a may be substantially the same as that discussed in FIGS. 14A and 14B. As a top surface of the preliminary first conductive pattern 113b is coplanar with a top surface of the preliminary inner dielectric pattern 115b, the top surface of the preliminary first conductive pattern 113b may be higher than the bottom surface 105b of the device isolation dielectric layer 105a.

A second conductive layer 118a may be formed on the preliminary inner dielectric pattern 115b and the preliminary first conductive pattern 113b. The formation of the second conductive layer 118a may be substantially the same as that discussed in FIGS. 15A and 15B.

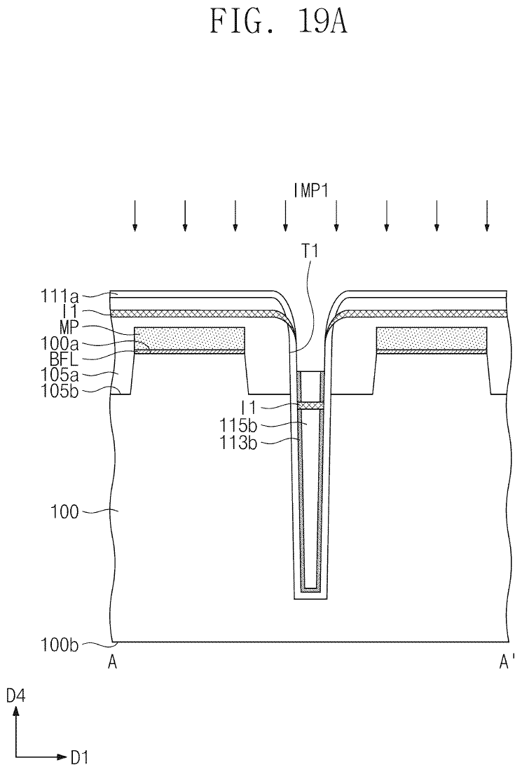

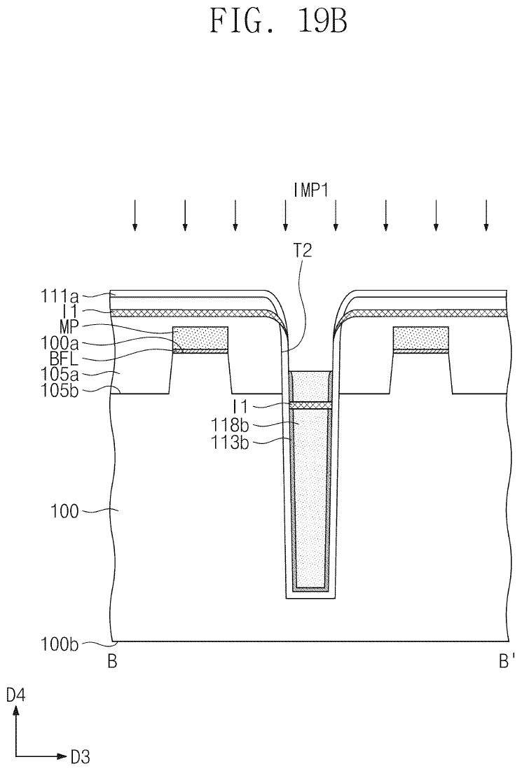

Referring to FIGS. 19A and 19B, a preliminary second conductive pattern 118b may be formed in the second trench T2. The preliminary second conductive pattern 118b may be formed by an etching process that removes a portion of the second conductive layer 118a. The etching process that removes a portion of the second conductive layer 118a may be substantially the same as that discussed in FIGS. 16A and 16B. For example, the second conductive layer 118a in the first trench T1 may all be removed, and the preliminary second conductive pattern 118b may be formed only in the second trench T2. The preliminary second conductive pattern 118b may be formed to have a top surface higher than the bottom surface 105b of the device isolation dielectric layer 105a.

A first impurity layer I1 may be formed on the semiconductor substrate 100. The first impurity layer I1 may be formed by a first ion implantation process IMP1 that dopes first impurities. The first ion implantation process IMP1 may be substantially the same as that discussed in FIGS. 12A and 12B.

In the first trench T1, the first impurity layer I1 may be formed in the preliminary first conductive pattern 113b and the preliminary inner dielectric pattern 115b. In the second trench T2, the first impurity layer I1 may be formed in the preliminary first conductive pattern 113b and the preliminary second conductive pattern 118b. For example, the first impurity layer I1 serving as an etch stop layer may be formed even in the second trench T2. In the first trench T1 and the second trench T2, the first impurity layer I1 may be formed lower than the bottom surface 105b of the device isolation dielectric layer 105a.

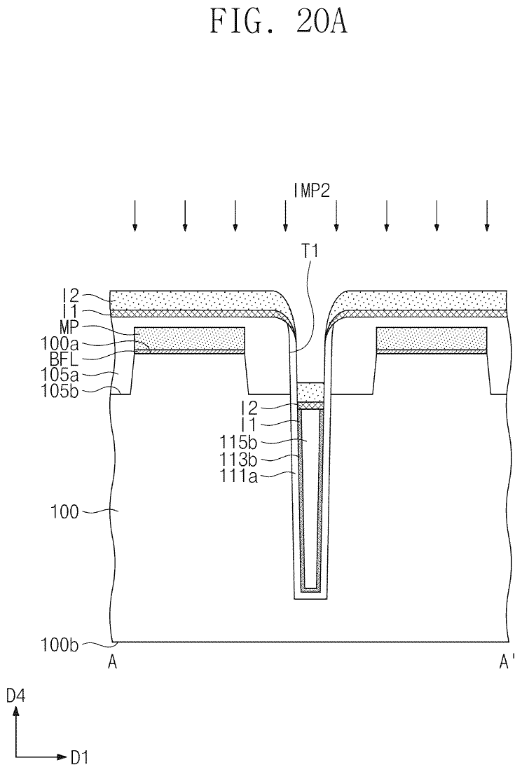

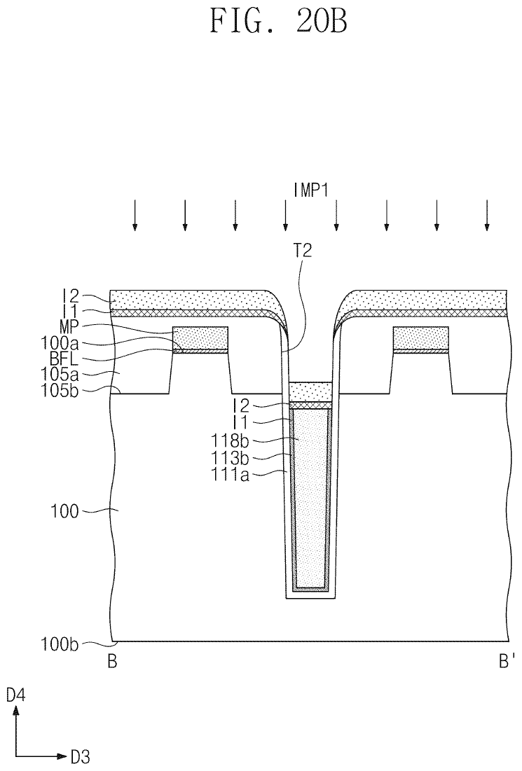

Referring to FIGS. 20A and 20B, a second impurity layer 12 may be formed on the semiconductor substrate 100. The second impurity layer 12 may be formed by a second ion implantation process IMP2 that dopes second impurities. The second ion implantation process IMP2 may be substantially the same as that discussed in FIGS. 13A and 13B.

The second impurity layer 12 may be formed on the first impurity layer I1. In the first trench T1 and the second trench T2, the second impurity layer 12 may be formed in the preliminary second conductive pattern 118b, the preliminary first conductive pattern 113b, and the preliminary inner dielectric pattern 115b positioned on the first impurity layer I1.

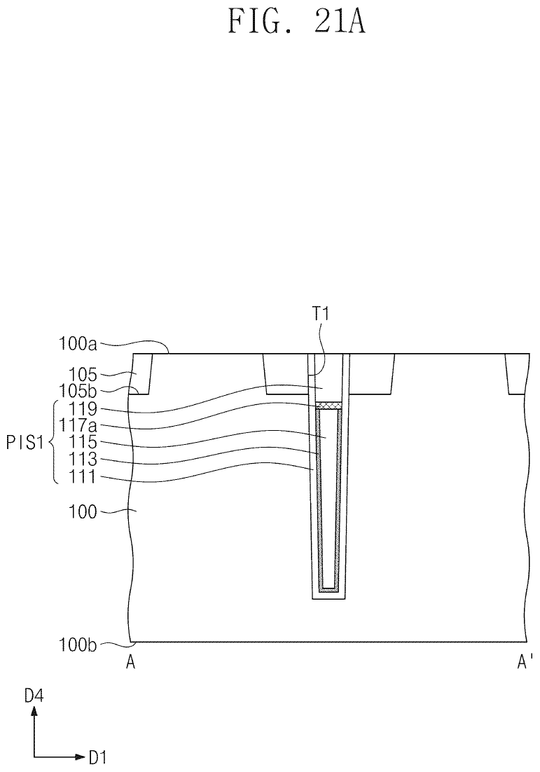

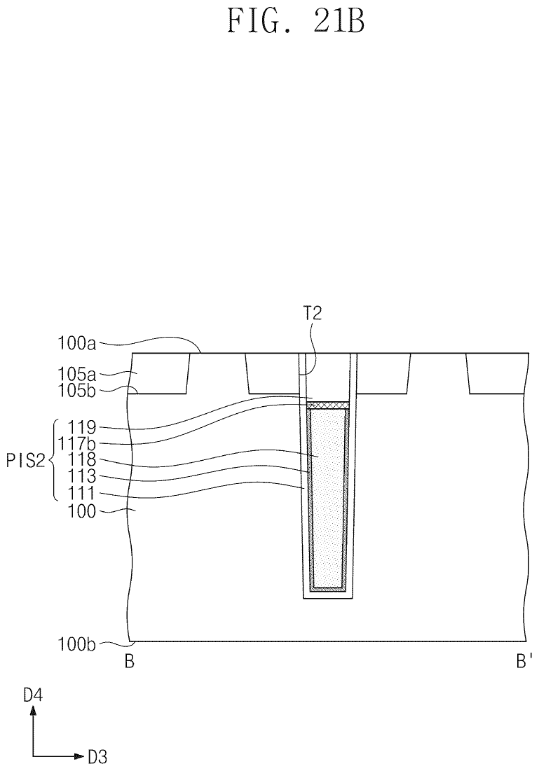

Referring to FIGS. 21A and 21B, a first pixel isolation structure PIS1 may be formed in the first trench T1. A second pixel isolation structure PIS2 may be formed in the second trench T2. The first pixel isolation structure PIS1 may include a first etch stop layer 117a, and the second pixel isolation structure PIS2 may include a second etch stop layer 117b. The first pixel isolation structure PIS1 and the second pixel isolation structure PIS2 may be substantially the same as that discussed in FIGS. 7A and 7B.

The second impurity layer 12 may be removed by a wet etching process. The wet etching process may be substantially the same as that discussed in FIGS. 13A and 13B. For example, a difference in etch rate between the first impurity layer I1 and the second impurity layer 12 may be used to remove the second impurity layer 12 and to leave the first impurity layer 11. Thus, the first impurity layer I1 in the first trench T1 may be formed into the first etch stop layer 117a, and the first impurity layer I1 in the second trench T2 may be formed into the second etch stop layer 117b.

The mask pattern MP may be removed, and a planarization process may be performed to expose the first surface 100a of the semiconductor substrate 100. The planarization process may be substantially the same as that discussed in FIGS. 16A and 16B.

A pixel circuit layer 20 and an optical transmission layer 30 of FIGS. 4A and 4B may be respectively formed on the first surface 100a and the second surface 100b of the semiconductor substrate 100, and this step may be substantially the same as that discussed above.

An image sensor according to some example embodiments may include a pixel isolation structure including an etch stop layer. In fabricating the image sensor, the etch stop layer may determine a level (or height) of a top surface of a first conductive pattern. There may thus be an increase in horizontal overlapping area between a semiconductor substrate and the first conductive pattern. Therefore, a negative bias applied to the first conductive pattern may sufficiently reduce a dark current of the image sensor, and accordingly the image sensor may improve in electrical and optical properties.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Moreover, when the words “generally” and “substantially” are used in connection with material composition, it is intended that exactitude of the material is not required but that latitude for the material is within the scope of the disclosure.

Further, regardless of whether numerical values or shapes are modified as “about” or “substantially,” it will be understood that these values and shapes should be construed as including a manufacturing or operational tolerance (e.g., +10%) around the stated numerical values or shapes. Thus, while the term “same,” “identical,” or “equal” is used in description of example embodiments, it should be understood that some imprecisions may exist. Thus, when one element or one numerical value is referred to as being the same as another element or equal to another numerical value, it should be understood that an element or a numerical value is the same as another element or another numerical value within a desired manufacturing or operational tolerance range (e.g., +10%).

Although inventive concepts have been described in connection with example embodiments illustrated in the accompanying drawings, it will be understood to those skilled in the art that various changes and modifications may be made without departing from the technical spirit and essential feature of example embodiments. It therefore will be understood that embodiments described above are just illustrative but not limitative in all aspects. Additionally, example embodiments are not necessarily mutually exclusive with one another. For example, some example embodiments may include one or more features described with reference to one or more figures, and may also include one or more other features described with reference to one or more other figures.

1. An image sensor, comprising:
a semiconductor substrate having a first conductivity type and including a first surface and a second surface opposite to each other;
a plurality of photoelectric conversion regions in the semiconductor substrate and having a second conductivity type; and
a first pixel isolation structure between the photoelectric conversion regions adjacent to each other in a first direction,
wherein the first pixel isolation structure includes,
a first conductive pattern adjacent to the semiconductor substrate and having a shape extending from the first surface to the second surface,
an inner dielectric pattern on an inner lateral surface of the first conductive pattern,
a buried dielectric pattern on the inner dielectric pattern, and
an etch stop layer between the inner dielectric pattern and the buried dielectric pattern.

2. The image sensor of claim 1, further comprising:
a second pixel isolation structure between the photoelectric conversion regions adjacent to each other in a second direction diagonal to the first direction,
wherein the second pixel isolation structure includes another portion of the first conductive pattern,
a second conductive pattern on the inner lateral surface of the other portion of first conductive pattern, and
another portion of the buried dielectric pattern on the second conductive pattern.

3. The image sensor of claim 2, wherein the first conductive pattern of the second pixel isolation structure has a thickness decreasing with decreasing distance from the first surface of the semiconductor substrate.

4. The image sensor of claim 2, wherein a top surface of the first conductive pattern included in the second pixel isolation structure is coplanar with a top surface of the second conductive pattern.

5. The image sensor of claim 2, wherein a top surface of the first conductive pattern included in the second pixel isolation structure is lower than a top surface of the second conductive pattern.

6. The image sensor of claim 2, wherein a bottom surface of the buried dielectric pattern included in the first pixel isolation structure and a bottom surface of the buried dielectric pattern included in the second pixel isolation structure are at different levels.

7. The image sensor of claim 2, wherein a width in the first direction of the first pixel isolation structure is less than a width in the second direction of the second pixel isolation structure.

8. The image sensor of claim 2, wherein, in the first pixel isolation structure, a portion of the second conductive pattern is between the etch stop layer and the buried dielectric pattern.

9. The image sensor of claim 2, wherein the first conductive pattern and the second conductive pattern include polysilicon.

10. The image sensor of claim 2, wherein the first direction and the second direction are parallel to the first surface and the second surface of the semiconductor substrate.

11. The image sensor of claim 1, wherein the etch stop layer includes at least one selected from carbon, silicon, argon, and boron.

12. The image sensor of claim 1, further comprising:
a device isolation layer in the semiconductor substrate and adjacent to the first surface, wherein
the first pixel isolation structure penetrates the device isolation layer, and
a bottom surface of the device isolation layer is higher than the etch stop layer.

13. The image sensor of claim 12, wherein a distance between the bottom surface of the device isolation layer and a top surface of the etch stop layer is in a range of 5 nm to 1,000 nm.

14. An image sensor, comprising:
a semiconductor substrate having a first conductivity type and including a first surface and a second surface that are opposite to each other;
a plurality of photoelectric conversion regions in the semiconductor substrate and having a second conductivity type;
a device isolation layer in the semiconductor substrate and adjacent to the first surface;
a first pixel isolation structure between two neighboring ones of the photoelectric conversion regions and including a first etch stop layer; and
a second pixel isolation structure between four neighboring ones of the photoelectric conversion regions and including a second etch stop layer,
wherein the first etch stop layer and the second etch stop layer are between a bottom surface of the device isolation layer and the second surface of the semiconductor substrate.

15. The image sensor of claim 14, wherein the first etch stop layer and the second etch stop layer independently include at least one selected from carbon, silicon, argon, and boron.

16. The image sensor of claim 14,
wherein the first pixel isolation structure includes,
an inner dielectric pattern between the first etch stop layer and the second surface and
a first portion of a first conductive pattern on opposite sides of the inner dielectric pattern, and
wherein the second pixel isolation structure includes,
a second conductive pattern between the second etch stop layer and the second surface, and
a second portion of the first conductive pattern on opposite sides of the second conductive pattern.

17. The image sensor of claim 14, wherein each of the first pixel isolation structure and the second pixel isolation structure has a width that decreases in a direction from the first surface to the second surface.

18. An image sensor, comprising:
a semiconductor substrate including a light-receiving area, a light-shielding area, and a pad area and having a first surface and a second surface opposite to each other;
a pixel isolation structure in the semiconductor substrate on the light-receiving area and the light-shielding area, the pixel isolation structure defining a plurality of pixel regions and including a first conductive pattern;
a transfer gate electrode on the first surface of the semiconductor substrate;
a plurality of photoelectric conversion regions in the semiconductor substrate on the light-receiving area and the light-shielding area;
a pixel circuit layer on the first surface of the semiconductor substrate; and
an optical transmission layer on the second surface of the semiconductor substrate,
wherein the pixel isolation structure includes,
a plurality of first pixel isolation structures between the pixel regions adjacent to each other in a first direction or a second direction intersecting the first direction, and
a plurality of second pixel isolation structures between the pixel regions adjacent to each other in a third direction diagonal to the first and second directions, wherein
the first pixel isolation structure further includes an inner dielectric pattern on an inner lateral surface of the first conductive pattern, and
the second pixel isolation structure further includes a second conductive pattern on the inner lateral surface of the first conductive pattern.

19. The image sensor of claim 18, wherein the first direction, the second direction, and the third direction are parallel to the first surface and the second surface.

20. The image sensor of claim 18, wherein the first pixel isolation structure further includes:
a buried dielectric pattern adjacent to the first surface; and
an etch stop layer between the inner dielectric pattern and the buried dielectric pattern,
wherein the etch stop layer includes at least one selected from carbon, silicon, argon, and boron.

21. (canceled)

22. (canceled)

23. (canceled)

24. (canceled)

25. (canceled)
